(19) United States
(12) Patent Application Publication
(10) Pub. No.: US 2026/0018464 A1
(43) Pub. Date: Jan. 15, 2026

(54) METHOD OF PROCESSING WAFER

(71) Applicant: DISCO CORPORATION, Tokyo (JP)

(72) Inventors: Makiko OHMAE, Tokyo (JP); Taro ARAKAWA, Tokyo (JP)

(21) Appl. No.: 19/236,306

(22) Filed: Jun. 12, 2025

(30) Foreign Application Priority Data
Jul. 12, 2024 (JP) 2024-112428

(51) Int. Cl. H01L 21/78; H01L 21/268

(52) U.S. Cl. CPC H01L 21/78; H01L 21/268

(57) ABSTRACT

A wafer processing method including applying a laser beam to the wafer along projected dicing lines of the wafer while focusing the laser beam within the wafer, thereby forming modified layers in the wafer along the projected dicing lines, after the modified layers have been formed in the wafer, affixing a first tape to a reverse side of the wafer, after the first tape has been affixed to the reverse side of the wafer, developing cracks initiated from the modified layers in the wafer to divide the wafer into a plurality of device chips, and expanding the first tape to form gaps between the device chips, and after the gaps have been formed between the device chips, inserting a cutting blade into the gaps and causing the cutting blade to cut into side faces of the device chips, thereby cutting off the side faces of the device chips.

### BACKGROUND OF THE INVENTION

### Field of the Invention

The present invention relates to a method of processing a wafer.

### Description of the Related Art

Semiconductor device chips that find widespread use in electric appliances such as cellular phones and illumination devices, for example, are fabricated by dividing a wafer made of semiconductor. Specifically, for example, projected dicing lines are established on a face side of the wafer. Such devices as integrated circuits (ICs) and light-emitting diodes (LEDs) are constructed in respective areas demarcated on the face side of the wafer by the projected dicing lines. The wafer with the devices on its face side is thinned down to a predetermined thickness by having a reverse side thereof ground by a grinding apparatus. Thereafter, the wafer is divided into pieces along the projected dicing lines by a processing apparatus such as a cutting apparatus having an annular cutting blade. The pieces are available as a plurality of semiconductor device chips having the respective devices.

Some semiconductor device chips that have LEDs as devices have been manufactured from a wafer made of sapphire having excellent optical transparency. Typically, wafers of sapphire are relatively high in hardness. When a cutting apparatus cuts a wafer made of a highly hard material such as sapphire with a cutting blade, the cutting blade is likely to be damaged unless it is of high mechanical strength, e.g., has a sufficiently large edge thickness.

However, the thicker the cutting blade is, the wider a kerf, i.e., a groove, cut in the wafer by the cutting blade is. As a result, the wafer suffers a reduced material volume available for use as device chips and causes an increased kerf loss.

One solution has been to use a laser processing apparatus, rather than a cutting apparatus having a cutting blade, for applying a laser beam to a wafer to divide the wafer along the projected dicing lines established thereon (see, for example, Japanese Patent Laid-open No. 2002-192370). The laser processing apparatus applies a laser beam having a wavelength transmittable through a wafer to the wafer while positioning its focused spot within the wafer, thereby forming modified layers in the wafer along the projected dicing lines thereon. Thereafter, external forces are applied to the wafer to develop cracks initiated from the modified layers in the wafer along the projected dicing lines. The wafer is thus divided along the projected dicing lines into a plurality of semiconductor device chips, i.e., LED chips.

### SUMMARY OF THE INVENTION

According to the process of dividing the wafer with the laser beam, however, some of the modified layers formed by the laser beam applied to the wafer are left on the LED chips and exposed on their side faces. Since the modified layers obstruct the emission of light from the LEDs, they reduce the brightness of the LEDs. Even if the devices in the device chips are not LEDs, the modified layers left on the device chips are likely to initiate rupture of the device chips and lower the strength of the device chips.

In view of this, it may be advisable to remove the modified layers from the device chips fabricated from the wafer. For example, external forces may be applied to the wafer to produce cracks in the wafer and divide the wafer. Thereafter, a cutting apparatus may cause a cutting blade to cut into the cracks and the modified layers to remove the modified layers from the wafer.

However, since the cracks have extremely small widths, the cutting blade undergoes a load that is essentially identical to the load applied thereto for cutting the wafer itself, so that the cutting blade tends to be damaged. To avoid such blade damage, the wafer needs to be cut by a cutting blade that is of high mechanical strength, e.g., has a large edge thickness. Inasmuch as the cutting blade with the large edge thickness cuts into those regions of the wafer where no modified layers are present, the cutting process gives rise to an increased kerf loss.

It is therefore an object of the present invention to provide a method of processing a wafer in such a manner as to be able to remove modified layers exposed on side faces of device chips fabricated from the wafer while at the same time reducing a kerf loss from the wafer.

In accordance with an aspect of the present invention, there is provided a method of processing a wafer to fabricate a plurality of device chips from the wafer by dividing the wafer along projected dicing lines established on a face side of the wafer, including applying a laser beam having a wavelength transmittable through the wafer to the wafer along the projected dicing lines while focusing the laser beam within the wafer, thereby forming modified layers in the wafer along the projected dicing lines, after the modified layers have been formed in the wafer, affixing a first tape to a reverse side, opposite the face side, of the wafer, after the first tape has been affixed to the reverse side of the wafer, developing cracks initiated from the modified layers in the wafer to divide the wafer into a plurality of device chips, and expanding the first tape to form gaps between the device chips, and after the gaps have been formed between the device chips, inserting a cutting blade into the gaps and causing the cutting blade to cut into side faces of the device chips, thereby cutting off the side faces of the device chips.

The gaps may be formed by pressing the wafer to develop the cracks therein before the first tape is expanded.

The device chips may include a first device chip having a first side face and a second device chip that is disposed adjacent to the first device chip and that has a second side face that faces the first side face of the first device chip, the cutting blade may have an annular first surface and an annular second surface opposite the annular first surface, the gaps may be formed between the first side face of the first device chip and the second side face of the second device chip, and the side faces of the device chips may be cut by causing the annular first surface of the cutting blade to cut into the first side face of the first device chip and causing the annular second surface of the cutting blade to cut into the second side face of the second device chip, thereby simultaneously cutting off the first side face of the first device chip and the second side face of the second device chip.

The cutting blade may include a layered cutting edge assembly having a first cutting edge having the annular first surface, a second cutting edge having the annular second surface, and a third cutting edge disposed between the first cutting edge and the second cutting edge, the third cutting edge may be more susceptible to wear than the first cutting edge, the third cutting edge may be more susceptible to wear than the second cutting edge, and the side faces of the device chips may be cut by causing the first cutting edge to cut off the first side face of the first device chip and causing the second cutting edge to cut off the second side face of the second device chip.

The method may further include, before forming the modified layers, affixing a second tape to the face side of the wafer, and, after forming the modified layers but before cutting off the side faces of the device chips, peeling off the second tape from the face side of the wafer, the modified layers may be formed by applying the laser beam to the wafer from the reverse side thereof, and the side faces of the device chips are cut off by inserting the cutting blade into the gaps from the face side of the wafer.

In the method of processing a wafer according to the aspect of the present invention, the laser beam is applied to the wafer to form the modified layers in the wafer, and the cracks initiated from the modified layers are developed in the wafer, thereby dividing the wafer into the device chips. The material loss, i.e., kerf loss, from the wafer thus processed is reduced compared with the process of cutting the wafer with the cutting blade to form dividing grooves in the wafer and dividing the wafer along the dividing grooves.

Moreover, after the wafer has been divided into the device chips, the first tape affixed to the wafer is expanded to form the gaps between the device chips. Thereafter, the cutting blade is inserted into the gaps and cuts off the side faces of the device chips. In this manner, the modified layers exposed on the side faces of the device chips are removed. As no material derived from the wafer 11 is present in the gaps, no material is lost by inserting the cutting blade into the gaps. Even though the cutting blade is used, since the cutting blade cuts the device chips by cutting into the side faces thereof to a minimum depth required to remove the modified layers, the material loss is reduced.

The above and other objects, features and advantages of the present invention and the manner of realizing them will become more apparent, and the invention itself will best be understood from a study of the following description and appended claims with reference to the attached drawings showing preferred embodiments of the invention.

### BRIEF DESCRIPTION OF THE DRAWINGS

FIG. 1 is a perspective view of a wafer;

FIG. 2 is a flowchart of a method of processing a wafer according to a first embodiment of the present invention;

FIG. 3 is a perspective view of a mounter apparatus and the wafer in a second tape affixing step of the method;

FIG. 4 is a cross-sectional view of the mounter apparatus and the wafer in the second tape affixing step of the method;

FIG. 5 is a side elevational view, partly in cross section, of a grinding apparatus and the wafer in a grinding step of the method;

FIG. 6 is a perspective view of a laser beam applying apparatus and the wafer in a modified layer forming step of the method;

FIG. 7 is a cross-sectional view of the laser beam applying apparatus and the wafer in the modified layer forming step of the method;

FIG. 8 is a perspective view of a mounter apparatus, the wafer, and a frame in a first tape affixing step of the method;

FIG. 9 is a cross-sectional view of the mounter apparatus, the wafer, and the frame in the first tape affixing step of the method;

FIG. 10 is a perspective view of a peeling apparatus, the wafer, and the frame in a second tape peeling step of the method;

FIG. 11 is a cross-sectional view of the peeling apparatus, the wafer, and the frame in the second tape peeling step of the method;

FIG. 12 is a side elevational view, partly in cross section, of a breaking apparatus, the wafer, and the frame in a gap forming step of the method;

FIG. 13 is a side elevational view, partly in cross section, of an expanding apparatus, the wafer, and the frame in the gap forming step of the method;

FIG. 14 is a side elevational view, partly in cross section, of the expanding apparatus, the wafer, and the frame in the gap forming step of the method;

FIG. 15 is a perspective view of a cutting apparatus and the wafer in a cutting step of the method;

FIG. 16 is a side elevational view, partly in cross section, of the cutting apparatus and the wafer in the cutting step of the method;

FIG. 17 is an enlarged fragmentary cross-sectional view of the wafer and a first tape in the cutting step of the method;

FIG. 18 is an enlarged fragmentary side elevational view, partly in cross section, of a cutting blade, the wafer, and the first tape in the cutting step of the method;

FIG. 19 is an enlarged fragmentary cross-sectional view of the wafer and the first tape in the cutting step of the method;

FIG. 20 is an enlarged fragmentary side elevational view, partly in cross section, of the cutting blade, the wafer, and the first tape in the cutting step of the method;

FIG. 21 is an enlarged fragmentary side elevational view, partly in cross section, of a cutting blade, a wafer, and a first tape in a cutting step of a method of processing a wafer according to a second embodiment of the present invention; and

FIG. 22 is an enlarged fragmentary side elevational view, partly in cross section, of a cutting blade, a wafer, and a first tape in a cutting step of a method of processing a wafer according to a third embodiment of the present invention.

### DETAILED DESCRIPTION OF THE PREFERRED EMBODIMENTS

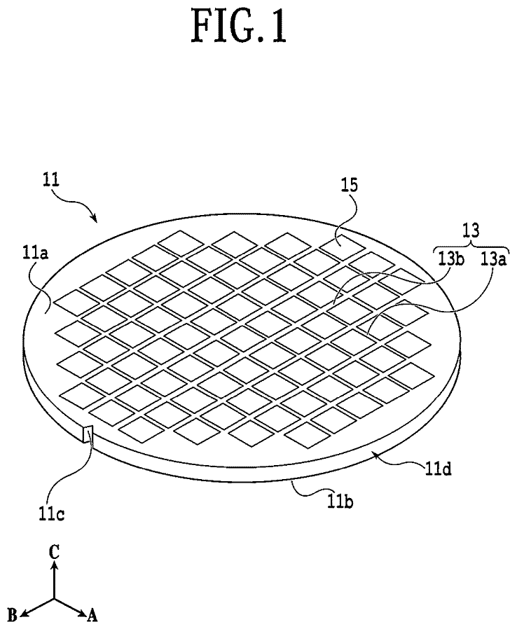

Preferred embodiments of the present invention will be described below with reference to the accompanying drawings. According to the preferred embodiments of the present invention, a wafer is divided into a plurality of device chips along projected dicing lines established on a face side of the wafer. First, a wafer will be described in detail below. FIG. 1 illustrates a wafer 11 in perspective.

As illustrated in FIG. 1, the wafer 11 is made of silicon (Si), silicon carbide (SiC), gallium nitride (GaN), or any of other semiconductor materials such as gallium arsenide (GaAs) and indium phosphide (InP), for example. Alternatively, the wafer 11 may be made of any of other materials including sapphire, glass, ceramic, resin, and metal, for example. The wafer 11 is of a disk shape having a circular first surface (face side) 11a and a circular second surface (reverse side) 11b opposite the first surface 11a. However, the wafer 11 is not limited to the materials and shape described above.

The wafer 11 has a notch 11c defined in a portion of its outer circumference or peripheral edge as a mark indicating the crystal orientation of the wafer 11 for wafer alignment. The wafer 11 may alternatively have an orientation flat in place of the notch 11c. Further alternatively, the wafer 11 may be free of the notch 11c or the orientation flat.

The peripheral edge of the first surface 11a of the wafer 11 is beveled to provide a round beveled face 11d for giving the wafer 11 increased mechanical strength. However, the wafer 11 may not have the round beveled face 11d.

A grid of projected dicing lines 13 is established on the first surface 11a. Specifically, the projected dicing lines 13 include a first group of projected dicing lines 13a extending parallel to a first direction, i.e., a direction along an A-axis indicated by an arrow A in FIG. 1, and a second group of projected dicing lines 13b extending parallel to a second direction, i.e., a direction along a B-axis indicated by an arrow B in FIG. 1, perpendicular to the first direction.

The projected dicing lines 13a and the projected dicing lines 13b demarcate a plurality of areas in the first surface 11a. The areas include respective devices 15 such as ICs, for example, constructed therein. However, the wafer 11 may be free of the projected dicing lines 13 and/or the devices 15.

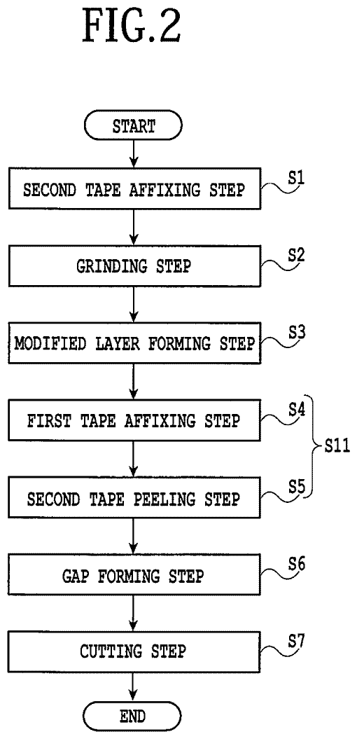

A method of processing a wafer, also referred to as a wafer processing method, according to a first embodiment will be described in detail below. FIG. 2 is a flowchart of the method of processing the wafer according to the first embodiment. As illustrated in FIG. 2, the wafer processing method includes a second tape affixing step S1, a grinding step S2, a modified layer forming step S3, a first tape affixing step S4, a second tape peeling step S5, a gap forming step S6, and a cutting step S7. The first tape affixing step S4 and the second tape peeling step S5 are collectively referred to as a tape replacing step S11.

In the wafer processing method according to the first embodiment, a laser beam is applied to the wafer 11 to form modified layers in the wafer 11 in the modified layer forming step S3. Thereafter, a first tape is affixed to the second surface 11b of the wafer 11 in the first tape affixing step S4. Thereafter, in the gap forming step S6, cracks initiated from the modified layers are developed in the wafer 11, thereby dividing the wafer 11 into a plurality of device chips. Then, the first tape is expanded to form gaps between the device chips. Subsequently, in the cutting step S7, a cutting blade is inserted into the gaps and forced to cut into the side faces of the device chips, thereby cutting off the side faces of the device chips.

Before the modified layers are formed in the wafer 11, a second tape may be affixed to the first surface 11a of the wafer 11. In this case, after the modified layers have been formed in the wafer 11 but before the cutting blade is forced to cut into the side faces of the device chips produced from the divided wafer 11, the second tape affixed to the first surface 11a of the wafer 11 is peeled off.

The steps of the wafer processing method will be described in detail below.

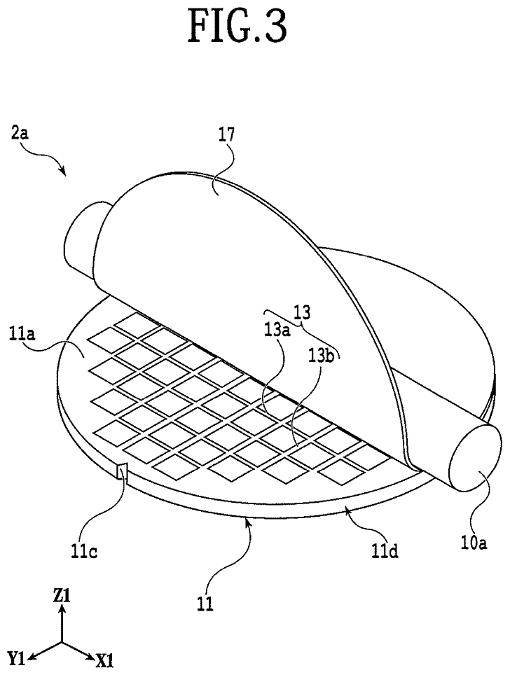

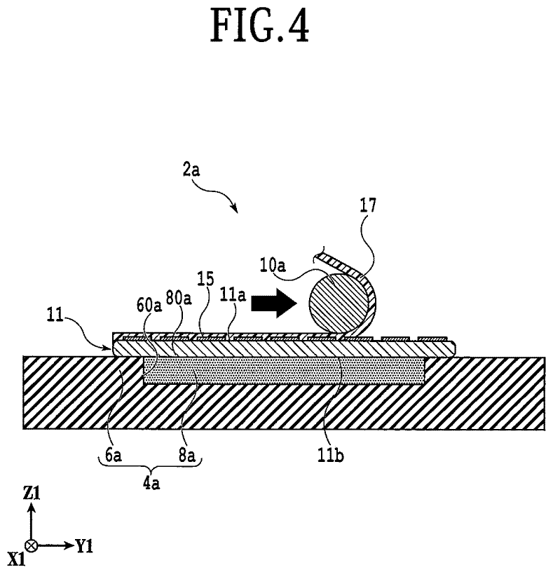

In the second tape affixing step S1, a second tape, i.e., a back-grinding tape, is affixed to the wafer 11. The second tape affixing step S1 is carried out by a mounter apparatus 2a (see FIGS. 3 and 4) that affixes the second tape to the wafer 11. FIG. 3 illustrates in perspective the mounter apparatus 2a and the wafer 11 in the second tape affixing step S1. FIG. 4 illustrates in cross section the mounter apparatus 2a and the wafer 11 in the second tape affixing step S1.

First, the mounter apparatus 2a will be described below. As illustrated in FIG. 4, the mounter apparatus 2a has a holding table 4a. The holding table 4a is omitted from illustration in FIG. 3.

The holding table 4a includes a disk-shaped frame 6a made of a metal material such as stainless steel, for example. The frame 6a has a circular recess 60a that is defined in an upper surface thereof and that has an upper circular opening that is open upwardly. A disk-shaped holding plate 8a that is commensurate in shape with the recess 60a is fitted in the recess 60a. The holding plate 8a is a porous plate made of a ceramic or the like, for example. The holding table 4a holds the wafer 11 placed on an upper holding surface 80a of the holding plate 8a.

The frame 6a has an unillustrated suction hole defined therein that has an end fluidly connected to the bottom of the recess 60a in the frame 6a. The suction hole has another end fluidly connected to an unillustrated suction channel that is fluidly connected to an unillustrated suction source. The suction channel has an unillustrated valve that can selectively be opened and closed. When the suction source is actuated and the valve is opened, a negative pressure developed by the suction source is transmitted through the suction channel, the suction hole, and the holding plate 8a and acts on the holding surface 80a. The suction source is a vacuum pump that is a combination of an air supply source and an ejector, for example. However, the suction source may alternatively be a rotary pump.

The mounter apparatus 2a has a roller 10a. The roller 10a is of a cylindrical shape and is made of a metal material such as stainless steel, for example. The roller 10a has a longitudinal axis extending in directions parallel to the holding surface 80a of the holding plate 8a, i.e., directions along an X1-axis indicated by an arrow X1 in FIGS. 3 and 4. The roller 10a is rotatable about its longitudinal axis along the X1-axis.

The mounter apparatus 2a also has an unillustrated Y1-axis moving mechanism for moving one of or both the roller 10a and the holding table 4a in a direction or directions parallel to the holding surface 80a of the holding plate 8a, i.e., a direction or directions along a Y1-axis indicated by an arrow Y1 in FIGS. 3 and 4. The Y1-axis moving mechanism is a ball-screw-type moving mechanism having a ball screw, for example. The Y1-axis moving mechanism moves the roller 10a and the holding table 4a relatively to each other in directions along the Y1-axis. The X1-axis and the Y1-axis extend horizontally perpendicularly to each other.

The mounter apparatus 2a also has an unillustrated cutter for cutting a web-shaped second tape 17 affixed to the wafer 11 into an appropriate shape and size. Alternatively, the mounter apparatus 2a affixes a second tape 17 that has been cut into an appropriate shape and size to the wafer 11.

The mounter apparatus 2a further includes one or more unillustrated delivery mechanisms disposed above the holding table 4a for delivering the wafer 11 onto the holding table 4a. Alternatively, an operator may manually deliver the wafer 11 onto the holding table 4a. In a case where the operator manually delivers the wafer 11, the one or more delivery mechanisms for delivering the wafer 11 may be dispensed with.

The second tape affixing step S1 is carried out by the mounter apparatus 2a described above. In the second tape affixing step S1, the wafer 11 is held on the holding table 4a. Specifically, the wafer 11 is placed on the holding table 4a by the delivery mechanism or mechanisms such that the first surface 11a of the wafer 11 is exposed upwardly and the second surface 11b thereof faces the holding surface 80a. Thereafter, the suction source is actuated and the valve is opened, transmitting the negative pressure from the suction source through the suction channel, the suction hole, and the holding table 4a. The negative pressure acts on the holding surface 80a, thereby attracting the wafer 11 under suction to the holding surface 80a and holding the wafer 11 on the holding table 4a.

Then, the second tape 17 is affixed to the first surface 11a of the wafer 11. The second tape 17 is a tape including a film-shaped base and an adhesive layer, i.e., a glue layer, deposited on the base. The base is made of resin such as polyolefin, polyvinyl chloride, or polyethylene terephthalate, for example, whereas the adhesive layer is made of an epoxy-based, acryl-based, or rubber-based adhesive, for example. The adhesive layer may alternatively be made of ultraviolet-curable resin that can be cured upon exposure to ultraviolet rays.

The second tape 17 is placed on the first surface 11a. While the roller 10a is pressing the second tape 17 against the first surface 11a of the wafer 11, the roller 10a and the holding table 4a are moved relatively to each other in directions along the Y1-axis parallel to the holding surface 80a of the holding plate 8a. The second tape 17 is now affixed to the first surface 11a of the wafer 11.

If the second tape 17 affixed to the wafer 11 is not cut in advance into a shape and size commensurate with the wafer 11 and is in the shape of a web, then the second tape 17 is cut by the cutter into a shape and size commensurate with the wafer 11. The wafer 11 with the second tape 17 affixed to the first surface 11a is thus obtained.

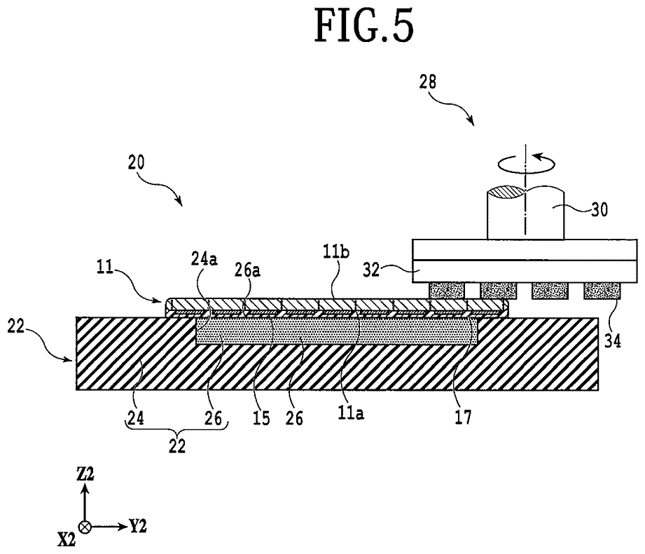

Then, the grinding step S2 of the wafer processing method is carried out. In the grinding step S2, the wafer 11 is thinned down to a predetermined thickness. FIG. 5 illustrates in side elevation, partly in cross section, a grinding apparatus 20 and the wafer 11 in the grinding step S2. The grinding step S2 is carried out by the grinding apparatus 20. As illustrated in FIG. 5, the grinding apparatus 20 has a holding table 22.

The holding table 22 is similar in structure to the holding table 4a of the mounter apparatus 2a. Specifically, the holding table 22 includes a disk-shaped frame 24 made of a metal material such as stainless steel, for example. The frame 24 has a circular recess 24a that is defined in an upper surface thereof and that has an upper circular opening that is open upwardly. A disk-shaped holding plate 26 that is commensurate in shape with the recess 24a is fitted in the recess 24a. The holding plate 26 is a porous plate made of a ceramic or the like, for example. The holding table 22 holds the wafer 11 placed on an upper holding surface 26a of the holding plate 26.

The frame 24 has an unillustrated suction hole defined therein that has an end fluidly connected to the bottom of the recess 24a in the frame 24. The suction hole has another end fluidly connected to an unillustrated suction channel that is fluidly connected to an unillustrated suction source. The suction channel has an unillustrated valve that can selectively be opened and closed. When the suction source is actuated and the valve is opened, a negative pressure developed by the suction source is transmitted through the suction channel, the suction hole, and the holding plate 26 and acts on the holding surface 26a. The suction source is a vacuum pump that is a combination of an air supply source and an ejector, for example. However, the suction source may alternatively be a rotary pump.

The holding table 22 is coupled to an unillustrated rotary actuator, such as an electric motor. When the rotary actuator is energized, it produces rotary drive power that rotates the holding table 22 about a vertical axis along a Z2-axis that extends through the center of the holding surface 26a perpendicularly to the holding surface 26a. The Z2-axis extends vertically and perpendicularly to an X2-axis indicated by an arrow X2 and a Y2-axis indicated by an arrow Y2. The X2-axis and the Y2-axis extend horizontally perpendicularly to each other.

The grinding apparatus 20 includes a grinding unit 28. The grinding unit 28 has an annular grinding wheel 32 and an annular array of grindstones 34 mounted on a lower surface of the grinding wheel 32 along an outer circumferential edge thereof. The grinding unit 28 also has a vertical spindle 30 having a lower end coupled to the grinding wheel 32 at its center. The spindle 30 has an upper end coupled to an unillustrated rotary actuator, such as an electric motor, for example. When the rotary actuator is energized, it produces rotary drive power that rotates the spindle 30 and the grinding wheel 32 about a vertical axis along the Z2-axis that extends through the center of the spindle 30 longitudinally along the spindle 30.

The grinding apparatus 20 also includes an unillustrated Z2-axis moving mechanism for moving one of or both the holding table 22 and the grinding unit 28 in a vertical direction or directions along the Z2-axis that extend perpendicularly to the holding surface 26a. The Z2-axis moving mechanism is a ball-screw-type moving mechanism having a ball screw, for example. The Z2-axis moving mechanism moves the holding table 22 and the grinding unit 28 relatively to each other in directions along the Z2-axis.

The grinding apparatus 20 further includes one or more unillustrated delivery mechanisms disposed above the holding table 22 for delivering the wafer 11 onto the holding table 22. Alternatively, the operator may manually deliver the wafer 11 onto the holding table 22. In a case where the operator manually delivers the wafer 11, the one or more delivery mechanisms for delivering the wafer 11 may be dispensed with.

The grinding step S2 is carried out by the grinding apparatus 20 described above. In the grinding step S2, the wafer 11 is held on the holding table 22. Specifically, the wafer 11 is placed on the holding table 22 by the delivery mechanism or mechanisms such that the second surface 11b of the wafer 11 is exposed upwardly and the first surface 11a thereof faces the holding surface 26a. Thereafter, the suction source is actuated and the valve is opened, transmitting the negative pressure from the suction source through the suction channel, the suction hole, and the holding plate 26. The negative pressure acts on the holding surface 26a, thereby attracting the wafer 11 under suction to the holding surface 26a and holding the wafer 11 on the holding table 22.

Then, the rotary actuator is energized to rotate the spindle 30 about the vertical axis along the Z2-axis, rotating the grinding wheel 32 and the grindstones 34 about the vertical axis. While the grinding wheel 32 and the grindstones 34 are being rotated about the vertical axis, the Z2-axis moving mechanism moves the holding table 22 and the grinding unit 28 relatively to each other in the directions along the Z2-axis, i.e., moves the holding table 22 and the grinding unit 28 toward each other. As illustrated in FIG. 5, the grindstones 34 are lowered to bring their lower surfaces into abrasive contact with the second surface 11b of the wafer 11, grinding the second surface 11b. In the grinding step S2, the wafer 11 is thinned down to a predetermined thickness.

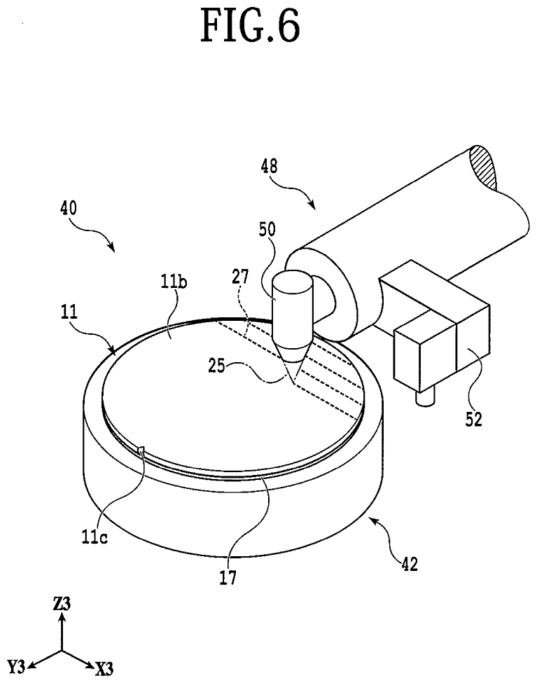

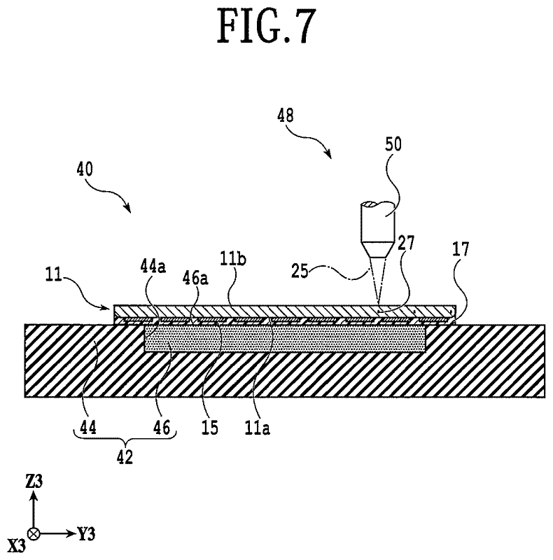

Then, the modified layer forming step S3 of the wafer processing method is carried out. In the modified layer forming step S3, modified layers that act as division initiating points are formed in the wafer 11. The modified layer forming step S3 is carried out by a laser beam applying apparatus 40 (see FIGS. 6 and 7). FIG. 6 illustrates in perspective the laser beam applying apparatus 40 and the wafer 11 in the modified layer forming step S3. FIG. 7 illustrates in cross section the laser beam applying apparatus 40 and the wafer 11 in the modified layer forming step S3.

First, the laser beam applying apparatus 40 will be described below.

As illustrated in FIGS. 6 and 7, the laser beam applying apparatus 40 has a holding table 42. The holding table 42 is similar in structure to the holding table 4a of the mounter apparatus 2a. Specifically, the holding table 42 includes a disk-shaped frame 44 made of a metal material such as stainless steel, for example. The frame 44 has a circular recess 44a that is defined in an upper surface thereof and that has an upper circular opening that is open upwardly. A disk-shaped holding plate 46 that is commensurate in shape with the recess 44a is fitted in the recess 44a. The holding plate 46 is a porous plate made of a ceramic or the like, for example. The holding table 42 holds the wafer 11 placed on an upper holding surface 46a of the holding plate 46.

The frame 44 has an unillustrated suction hole defined therein that has an end fluidly connected to the bottom of the recess 44a in the frame 44. The suction hole has another end fluidly connected to an unillustrated suction channel that is fluidly connected to an unillustrated suction source. The suction channel has an unillustrated valve that can selectively be opened and closed. When the suction source is actuated and the valve is opened, a negative pressure developed by the suction source is transmitted through the suction channel, the suction hole, and the holding plate 46 and acts on the holding surface 46a. The suction source is a vacuum pump that is a combination of an air supply source and an ejector, for example. However, the suction source may alternatively be a rotary pump.

The holding table 42 is coupled to an unillustrated rotary actuator, such as an electric motor. When the rotary actuator is energized, it produces rotary drive power that rotates the holding table 42 about a vertical axis along a Z3-axis indicated by an arrow Z3 that extends through the center of the holding surface 46a perpendicularly to the holding surface 46a. The Z3-axis extends vertically and perpendicularly to an X3-axis indicated by an arrow X3 and a Y3-axis indicated by an arrow Y3. The X3-axis and the Y3-axis extend horizontally perpendicularly to each other.

The laser beam applying apparatus 40 has a laser beam applying unit 48 for applying a laser beam 25 to the wafer 11 held on the holding table 42. The laser beam applying unit 48 includes an unillustrated laser oscillator. The laser oscillator includes a laser medium such as neodymium-doped yttrium aluminum garnet (Nd:YAG), for example, capable of laser oscillation.

The laser beam applying unit 48 also includes a processing head, i.e., a laser processing head, 50 and unillustrated optical components including a deflector and a beam condenser for guiding the laser beam 25 emitted by laser oscillation of the laser oscillator to the processing head 50. The laser beam 25 emitted from the laser oscillator is transmitted via the deflector, the beam condenser, and the processing head 50 and applied to the wafer 11 held on the holding table 42, thereby processing the wafer 11. The beam condenser includes an unillustrated condensing lens.

The laser beam applying apparatus 40 also includes an unillustrated processing head moving mechanism for moving the laser beam applying unit 48, i.e., the processing head 50, in directions along the Z3-axis. The processing head moving mechanism is a ball-screw-type moving mechanism having a ball screw, for example. The processing head moving mechanism moves the processing head 50 along the Z3-axis, i.e., selectively lifts and lowers the processing head 50, to adjust the height or vertical position of a focused spot of the laser beam 25 applied from the processing head 50.

As illustrated in FIG. 6, a camera 52 for capturing images of the wafer 11 held on the holding table 42 is disposed in a position adjacent to the processing head 50 along a direction parallel to the holding surface 46a of the holding plate 46, i.e., a direction along the X3-axis. Positions where the laser beam 25 is applied to the wafer 11 are determined in reference to images captured by the camera 52. The camera 52 is coupled to the processing head moving mechanism, as with the processing head 50. Therefore, the camera 52 is movable in unison with the processing head 50 along the Z3-axis by the processing head moving mechanism.

The laser beam applying apparatus 40 has an unillustrated X3-axis moving mechanism for moving the holding table 42 and the processing head 50 relatively to each other in directions parallel to the holding surface 46a of the holding plate 46 and along the X3-axis. The laser beam applying apparatus 40 also has an unillustrated Y3-axis moving mechanism for moving the holding table 42 and the processing head 50 relatively to each other in directions parallel to the holding surface 46a of the holding plate 46 and perpendicular to the X3-axis, i.e., directions along the Y3-axis.

Each of the X3-axis moving mechanism and the Y3-axis moving mechanism is a ball-screw-type moving mechanism having a ball screw, for example. When the laser beam 25 emitted from the processing head 50 is applied to the wafer 11 held on the holding table 42 while the holding table 42 and the processing head 50 are being moved relatively to each other by the X3-axis moving mechanism and the Y3-axis moving mechanism, the wafer 11 is processed by the laser beam 25 at predetermined positions on the wafer 11. Hereinafter, it is assumed by way of example that the holding table 42 is moved by the X3-axis moving mechanism and the Y3-axis moving mechanism while the processing head 50 remains unmoved along the X3-axis and the Y3-axis.

The laser beam applying apparatus 40 further includes one or more unillustrated delivery mechanisms disposed above the holding table 42 for delivering the wafer 11 onto the holding table 42. The wafer 11 is placed on the holding table 42 by the delivery mechanism or mechanisms such that the second surface 11b of the wafer 11 is exposed upwardly and the first surface 11a with the second tape 17 affixed thereto faces the holding surface 46a of the holding table 42. Alternatively, the operator may manually deliver the wafer 11 onto the holding table 42. In a case where the operator manually delivers the wafer 11, the one or more delivery mechanisms for delivering the wafer 11 may be dispensed with.

The modified layer forming step S3 is carried out by the laser beam applying apparatus 40 described above. In the modified layer forming step S3, the wafer 11 is held on the holding table 42. Specifically, the wafer 11 is placed on the holding table 42 such that the second tape 17 affixed to the first surface 11a of the wafer 11 is held in contact with the holding surface 46a. Thereafter, the suction source is actuated and the valve is opened to transmit the negative pressure from the suction source through the suction channel, the suction hole, and the holding plate 46, so that the negative pressure acts on the holding surface 46a. The wafer 11 is thus attracted under suction to the holding surface 46a and held on the holding table 42.

Then, the laser beam 25 is applied to the wafer 11 along the projected dicing lines 13. Specifically, the rotary actuator coupled to the holding table 42 is energized to turn the holding table 42 about its vertical axis until the first group of projected dicing lines 13a is oriented parallel to the X3-axis.

Then, the positional relation between the processing head 50 and the wafer 11 is adjusted. Specifically, the position of the holding table 42 is adjusted by the Y3-axis moving mechanism to align the processing head 50 with an extension of one of the projected dicing lines 13a at a position spaced radially outwardly of the wafer 11.

The height of the processing head 50 is adjusted by the processing head moving mechanism to position the focused spot of the laser beam 25 at a predetermined height or vertical position. The predetermined height or vertical position refers to a height or vertical position where the focused spot of the laser beam 25 can be located within the wafer 11 to form a modified layer in the wafer 11.

Further, the processing head 50 starts applying the laser beam 25 to the wafer 11. The laser beam 25 has a wavelength transmittable through the wafer 11. While the focused spot of the laser beam 25 is being kept at the predetermined height or vertical position, the holding table 42 is moved in a direction along the X3-axis by the X3-axis moving mechanism. Thus, the laser beam 25 that remains focused within the wafer 11 is continuously applied to the wafer 11 along the projected dicing line 13a aligned with the processing head 50, forming a modified layer 27 in the wafer 11 along the projected dicing line 13a.

If the wafer 11 is made of sapphire, then the laser beam 25 may be applied under the following conditions: For example, the laser beam 25 has a wavelength in the range of 515 to 1064 nm, a pulse duration in the range of 250 fs to 10 ps, an output power level in the range of 0.01 to 10 W, and a repetitive frequency in the range of 10 to 500 kHz, the condensing lens has a numerical aperture (NA) in the range of 0.6 to 0.8, and the wafer 11 is moved at a feed speed in the range of 10 to 2000 mm/s.

The output power level of the laser beam 25 is appropriately adjusted depending on the wavelength and pulse duration of the laser beam 25. The feed speed is appropriately adjusted depending on the repetitive frequency of the laser beam 25. Specifically, the wavelength may be set to 1064 nm, the pulse duration to 1 ps, the output power level to 0.5 W, the repetitive frequency to 10 kHz, and the feed speed to 800 mm/s, for example. However, the conditions under which the laser beam 25 is applied may be varied in such ranges as to allow a modified layer 27 to be formed adequately in the wafer 11.

After the laser beam 25 has been applied to the wafer 11 along the projected dicing line 13a aligned with the processing head 50 from one end to the other end thereof, the X3-axis moving mechanism stops moving the holding table 42 along the X3-axis. The processing head 50 also stops applying the laser beam 25 to the wafer 11.

Then, the Y3-axis moving mechanism moves the holding table 42 to align the processing head 50 with an end of the next projected dicing line 13a that has not been processed. The processing head 50 starts applying the laser beam 25 to the wafer 11, and the X3-axis moving mechanism starts moving the holding table 42 in a direction along the X3-axis to form a modified layer 27 in the wafer 11 along the next projected dicing line 13a from one end to the other thereof. The above process is repeated until modified layers 27 are formed in the wafer 11 along all the parallel projected dicing lines 13a of the first group.

Thereafter, the holding table 42 that is holding the wafer 11 thereon is turned 90 degrees about its vertical axis until the second group of projected dicing lines 13b is oriented parallel to the X3-axis. Then, the above process is repeated until modified layers 27 are formed in the wafer 11 along all the parallel projected dicing lines 13b of the second group. In the modified layer forming step S3, consequently, the laser beam 25 is applied to the wafer 11 to form the modified layers 27 therein along all the projected dicing lines 13 established on the wafer 11 in the manner described above. The modified layers 27 may be formed in the wafer 11 according to different sequences. For example, the modified layers 27 may first be formed along the projected dicing lines 13b of the second group and then along the projected dicing lines 13a of the first group.

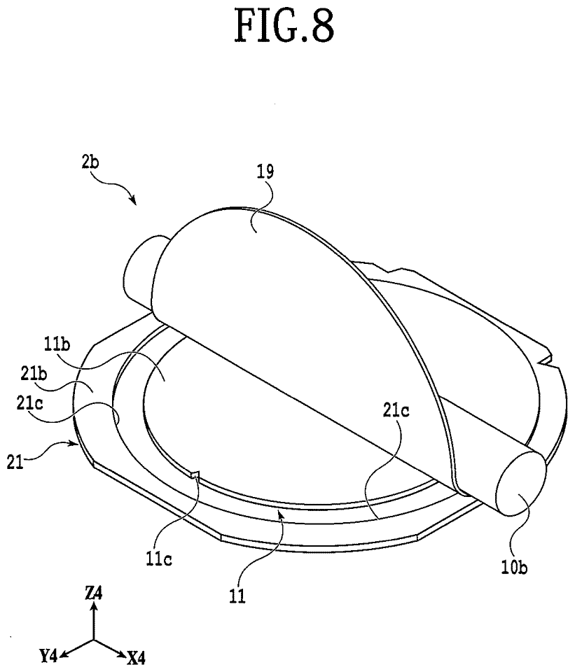

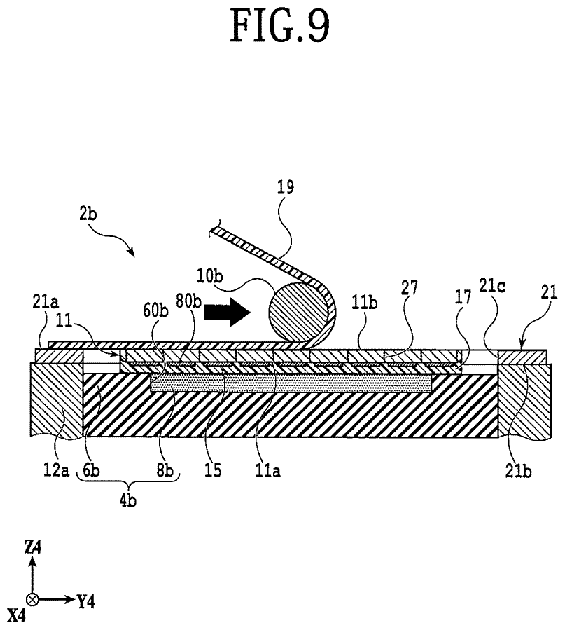

The modified layer forming step S3 is followed by the first tape affixing step S4. In the first tape affixing step S4, a first tape is affixed to the second surface 11b of the wafer 11. The first tape affixing step S4 is carried out by a mounter apparatus 2b (see FIGS. 8 and 9) that affixes the first tape to the wafer 11. FIG. 8 illustrates in perspective the mounter apparatus 2b, the wafer 11, and a frame 21 in the first tape affixing step S4. FIG. 9 illustrates in cross section the mounter apparatus 2b, the wafer 11, and the frame 21 in the first tape affixing step S4.

The mounter apparatus 2b used in the first tape affixing step S4 is structurally similar to the mounter apparatus 2a used in the second tape affixing step S1. Hence, the description of the mounter apparatus 2a is incorporated by way of reference herein. As illustrated in FIG. 9, the mounter apparatus 2b has a holding table 4b. The holding table 4b is omitted from illustration in FIG. 8.

The holding table 4b is similar in structure to the holding table 4a of the mounter apparatus 2a. The holding table 4b includes a disk-shaped frame 6b made of a metal material such as stainless steel, for example. The frame 6b has a circular recess 60b that is defined in an upper surface thereof and that has an upper circular opening that is open upwardly. A disk-shaped holding plate 8b that is commensurate in shape with the recess 60b is fitted in the recess 60b. The holding plate 8b is a porous plate made of a ceramic or the like, for example. The holding table 4b holds the wafer 11 placed on an upper holding surface 80b of the holding plate 8b.

The frame 6b has an unillustrated suction hole defined therein that has an end fluidly connected to the bottom of the recess 60b in the frame 6b. The suction hole has another end fluidly connected to an unillustrated suction channel that is fluidly connected to an unillustrated suction source. The suction channel has an unillustrated valve that can selectively be opened and closed. When the suction source is actuated and the valve is opened, a negative pressure developed by the suction source is transmitted through the suction channel, the suction hole, and the holding plate 8b and acts on the holding surface 80b. The suction source is a vacuum pump that is a combination of an air supply source and an ejector, for example. However, the suction source may alternatively be a rotary pump.

The mounter apparatus 2b has a roller 10b. The roller 10b is of a cylindrical shape and is made of a metal material such as stainless steel, for example. The roller 10b has a longitudinal axis extending in directions parallel to the holding surface 80b of the holding plate 8b, i.e., directions along an X4-axis indicated by an arrow X4 in FIGS. 8 and 9. The roller 10b is rotatable about its longitudinal axis along the X4-axis.

The mounter apparatus 2b also has an unillustrated Y4-axis moving mechanism for moving one of or both the roller 10b and the holding table 4b in a direction or directions parallel to the holding surface 80b of the holding plate 8b, i.e., a direction or directions along a Y4-axis indicated by an arrow Y4 in FIGS. 8 and 9. The Y4-axis moving mechanism is a ball-screw-type moving mechanism having a ball screw, for example. The Y4-axis moving mechanism moves the roller 10b and the holding table 4b relatively to each other in directions along the Y4-axis. The X4-axis and the Y4-axis extend horizontally perpendicularly to each other.

The mounter apparatus 2b further includes a support member 12a. The support member 12a is a hollow cylindrical member made of a metal material such as stainless steel, for example, and disposed in surrounding relation to the holding table 4b. The mounter apparatus 2b also includes a Z4-axis moving mechanism for moving the support member 12a in directions perpendicular to the holding surface 80b of the holding plate 8b, i.e., in directions along a Z4-axis indicated by the arrow Z4 in FIGS. 8 and 9. The Z4-axis moving mechanism is a ball-screw-type moving mechanism having a ball screw, for example. The Z4-axis extends vertically and perpendicularly to the X4-axis and the Y4-axis.

The mounter apparatus 2b also has an unillustrated cutter for cutting a web-shaped first tape 19 affixed to the wafer 11 into an appropriate shape and size. Alternatively, the mounter apparatus 2b affixes a first tape 19 that has been cut into an appropriate shape and size to the wafer 11.

The mounter apparatus 2b further includes one or more unillustrated delivery mechanisms disposed above the holding table 4b for delivering the wafer 11 onto the holding table 4b. Alternatively, the operator may manually deliver the wafer 11 onto the holding table 4b. In a case where the operator manually delivers the wafer 11, the one or more delivery mechanisms for delivering the wafer 11 may be dispensed with.

The first tape affixing step S4 is carried out by the mounter apparatus 2b described above. In the first tape affixing step S4, the wafer 11 is held on the holding table 4b. Specifically, the wafer 11 is placed on the holding table 4b by the delivery mechanism or mechanisms such that the second tape 17 affixed to the first surface 11a of the wafer 11 is held in contact with the holding surface 80b. Thereafter, the suction source is actuated and the valve is opened, transmitting the negative pressure from the suction source through the suction channel, the suction hole, and the holding table 4b. The negative pressure acts on the holding surface 80b, thereby attracting the wafer 11 under suction to the holding surface 80b and holding the wafer 11 on the holding table 4b.

Then, the frame 21 is prepared. The frame 21 is made of a metal material such as stainless steel (SUS), for example. The frame 21 is of an annular shape and has an annular first surface 21a and an annular second surface 21b opposite the first surface 21a. The frame 21 has a circular opening 21c defined centrally therein and extending axially, i.e., thicknesswise, through the frame 21. The opening 21c is larger in diameter than the wafer 11, i.e., larger in width than the first surface 11a and the second surface 11b of the wafer 11.

The second surface 21b of the frame 21 is placed on the support member 12a in such a manner as to put the wafer 11 in the opening 21c of the frame 21. At this time, the position of the support member 12a along the Z4-axis is adjusted by the Z4-axis moving mechanism to equalize the heights of the first surface 21a of the frame 21 and the second surface 11b of the wafer 11.

Then, the first tape 19 is affixed to the second surface 11b of the wafer 11. The first tape 19 is a tape including a film-shaped base and an adhesive layer, i.e., a glue layer, deposited on the base. The base is made of resin such as polyolefin, polyvinyl chloride, or polyethylene terephthalate, for example, whereas the adhesive layer is made of an epoxy-based, acryl-based, or rubber-based adhesive, for example. The base should preferably be made of a somewhat hard material in order to minimize vibrations caused when a cutting blade cuts into the first tape 19 in the cutting step S7 to be described later. In view of this, the base of the first tape 19 should preferably be made of polyethylene terephthalate. The adhesive layer may alternatively be made of ultraviolet-curable resin that can be cured upon exposure to ultraviolet rays.

The first tape 19 is placed on the second surface 11b of the wafer 11. The roller 10b is rotated about its longitudinal axis while pressing the first tape 19 against the second surface 11b and the first surface 21a of the frame 21. At the same time, the roller 10b and the holding table 4b are moved relatively to each other in directions along the Y4-axis. The first tape 19 is now affixed to the second surface 11b and the first surface 21a. The first tape 19 is cut by the cutter into an appropriate size and shape commensurate with the size, i.e., width, and shape of the frame 21. In the first tape affixing step S4 described above, the first tape 19 is affixed to the wafer 11 and the frame 21, so that the wafer 11 is integrally combined with the frame 21 by the first tape 19.

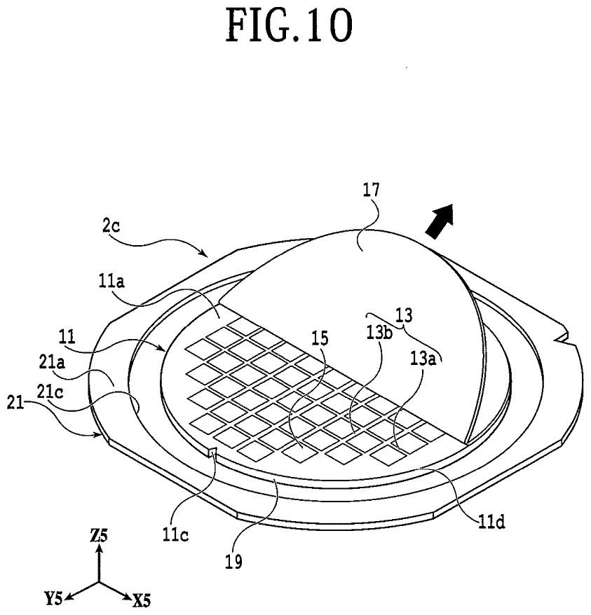

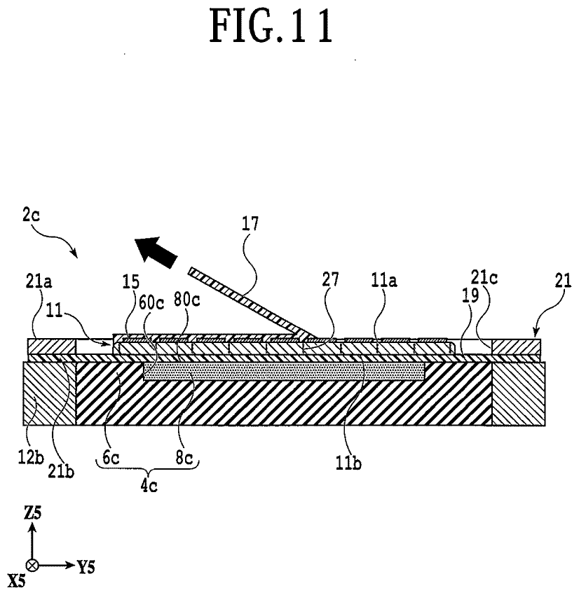

After the first tape affixing step S4, the second tape peeling step S5 is carried out. In the second tape peeling step S5, the second tape 17 affixed to the wafer 11 is peeled off. The second tape peeling step S5 is carried out by a peeling apparatus 2c (see FIGS. 10 and 11). FIG. 10 illustrates in perspective the peeling apparatus 2c, the wafer 11, and the frame 21 in the second tape peeling step S5. FIG. 11 illustrates in cross section the peeling apparatus 2c, the wafer 11, and the frame 21 in the second tape peeling step S5. As illustrated in FIG. 11, the peeling apparatus 2c has a holding table 4c. The holding table 4c is omitted from illustration in FIG. 10.

The holding table 4c is similar in structure to the holding table 4b of the mounter apparatus 2b. The holding table 4c includes a disk-shaped frame 6c made of a metal material such as stainless steel, for example. The frame 6c has a circular recess 60c that is defined in an upper surface thereof and that has an upper circular opening that is open upwardly. A disk-shaped holding plate 8c that is commensurate in shape with the recess 60c is fitted in the recess 60c. The holding plate 8c is a porous plate made of a ceramic or the like, for example. The holding table 4c holds the wafer 11 placed on an upper holding surface 80c of the holding plate 8c.

The frame 6c has an unillustrated suction hole defined therein that has an end fluidly connected to the bottom of the recess 60c in the frame 6c. The suction hole has another end fluidly connected to an unillustrated suction channel that is fluidly connected to an unillustrated suction source. The suction channel has an unillustrated valve that can selectively be opened and closed. When the suction source is actuated and the valve is opened, a negative pressure developed by the suction source is transmitted through the suction channel, the suction hole, and the holding plate 8c and acts on the holding surface 80c. The suction source is a vacuum pump that is a combination of an air supply source and an ejector, for example. However, the suction source may alternatively be a rotary pump.

The peeling apparatus 2c further includes one or more unillustrated delivery mechanisms disposed above the holding table 4c for delivering the wafer 11 onto the holding table 4c. The wafer 11 is placed on the holding surface 80c of the holding table 4c by the delivery mechanism or mechanisms such that the second tape 17 affixed to the first surface 11a of the wafer 11 is exposed upwardly and the first tape 19 affixed to the second surface 11b thereof is held in contact with the holding surface 80c. Alternatively, the operator may manually deliver the wafer 11 onto the holding table 4c. In a case where the operator manually delivers the wafer 11, the one or more delivery mechanisms for delivering the wafer 11 may be dispensed with.

The peeling apparatus 2c includes an unillustrated peeling mechanism. The peeling mechanism affixes a peeling adhesive tape to the second tape 17 affixed to the wafer 11 and lifts the peeling adhesive tape from the wafer 11, thereby peeling off the second tape 17 from the wafer 11. Specifically, the peeling adhesive tape is affixed to an end of the second tape 17 and then pulled to peel off the second tape 17 from the wafer 11 progressively from the end of the second tape 17 toward an opposite end thereof.

The second tape peeling step S5 is carried out by the peeling apparatus 2c described above. In the second tape peeling step S5, the wafer 11 is held on the holding table 4c. Specifically, the wafer 11 is placed on the holding table 4c by the delivery mechanism or mechanisms such that the second surface 11b of the wafer 11 faces the holding surface 80c. Alternatively, the operator may manually place the wafer 11 onto the holding table 4c. Thereafter, the suction source is actuated and the valve is opened to transmit the negative pressure from the suction source through the suction channel, the suction hole, and the holding plate 8c, so that the negative pressure acts on the holding surface 80c. The wafer 11 is thus attracted under suction to the holding surface 80c and held on the holding table 4c.

Then, the peeling mechanism lifts one end of the second tape 17 and peels off the second tape 17 from the first surface 11a of the wafer 11 progressively from the end of the second tape 17 toward an opposite end thereof. Alternatively, the operator may manually peel off the second tape 17 from the wafer 11.

Through the above-mentioned first tape affixing step S4 and the second tape peeling step S5, the tape affixed to the wafer 11 is replaced with the first tape 19 from the second tape 17. The first tape affixing step S4 and the second tape peeling step S5 may be switched around. In other words, the first tape affixing step S4 may be carried out after the second tape peeling step S5 has been carried out.

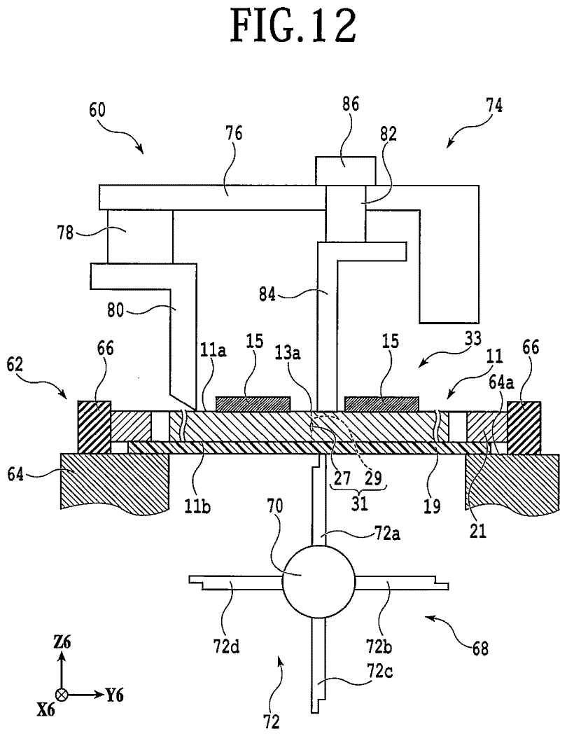

Then, the gap forming step S6 is carried out. In the gap forming step S6, cracks initiated from the modified layers 27 formed in the wafer 11 are developed in the wafer 11. Cracks are developed in the wafer 11 by a breaking apparatus 60 (see FIG. 12). FIG. 12 illustrates in side elevation, partly in cross section, the breaking apparatus 60, the wafer 11, and the frame 21 in the gap forming step S6. As illustrated in FIG. 12, the breaking apparatus 60 has a holding table 62 for holding the wafer 11 thereon. The holding table 62 has a support member 64. The support member 64 is a hollow cylindrical member made of a metal material such as stainless steel, for example.

A plurality of clamps 66 are disposed on an annular upper surface 64a of the support member 64. The clamps 66 are positioned on the upper surface 64a at equal angular spaced intervals in a circular pattern concentric with the upper surface 64a. For example, the clamps 66 include four clamps 66 disposed at angular spaced intervals of 90 degrees on the upper surface 64a. In FIG. 12, two of the four clamps 66 are illustrated.

Some of the clamps 66 are fixed clamps secured to the support member 64, whereas the remaining clamps 66 are movable clamps movable toward the center of the support member 64. For example, of the four clamps 66, two adjacent clamps 66 are fixed clamps, and the other two adjacent clamps 66 are movable clamps.

The breaking apparatus 60 includes an unillustrated Y6-axis moving mechanism for moving the holding table 62 along a Y6-axis that extends horizontally parallel to the upper surface 64a of the support member 64. The Y6-axis moving mechanism is a ball-screw-type moving mechanism having a ball screw, for example. The Y6-axis moving mechanism moves the support member 64 in directions along the Y6-axis relatively to a lower unit 68 and an upper unit 74 to be described below. The support member 64 is coupled to an unillustrated rotary actuator, such as an electric motor. When the rotary actuator is energized, it generates rotary drive power that rotates the support member 64 about a vertical axis extending through the center of the upper surface 64a and parallel to a Z6-axis that extends vertically perpendicularly to the Y6-axis.

As illustrated in FIG. 12, the lower unit 68 is disposed below the support member 64. The lower unit 68 grips the wafer 11 supported on the support member 64, in cooperation with an upper pressing bar 84 of the upper unit 74. The lower unit 68 includes a plurality of lower pressing bars 72 and a spherical bar holder 70 to which the lower pressing bars 72 are fixed. The lower pressing bars 72 extend radially outwardly from the bar holder 70.

Specifically, as illustrated in FIG. 12, the lower pressing bars 72 include four lower pressing bars 72a, 72b, 72c, and 72d having respective different lengths in directions along an X6-axis that extends parallel to the upper surface 64a and horizontally perpendicularly to the Y6-axis. Each of the lower pressing bars 72a, 72b, 72c, and 72d has a radially outer stepped end and a radially inner end secured to the bar holder 70. The lower pressing bars 72a, 72b, 72c, and 72d are angularly spaced at equally spaced angular intervals of 90 degrees around the bar holder 70.

The breaking apparatus 60 includes an unillustrated lower unit moving mechanism for moving the lower unit 68 along the Z6-axis that extends perpendicularly to the X6-axis and the Y6-axis. The lower unit moving mechanism is a ball-screw-type moving mechanism having a ball screw, for example. The lower unit moving mechanism moves the bar holder 70 in directions along the Z6-axis.

The bar holder 70 is coupled to an unillustrated rotary actuator, such as an electric motor. When the rotary actuator is energized, it produces rotary drive power that rotates the bar holder 70 about its horizontal axis extending through the center thereof along the X6-axis. When the bar holder 70 is rotated by the rotary actuator, the lower pressing bars 72a, 72b, 72c, and 72d are selectively brought into a position where they can cooperate with the upper pressing bar 84 of the upper unit 74.

As illustrated in FIG. 12, the upper unit 74 is disposed above the holding table 62. The upper unit 74 includes an L-shaped slider 76 extending mainly along the Y6-axis. The upper pressing bar 84 is fixed to the slider 76 by a support 82. A damper 86 coupled to the support 82 is disposed on the slider 76. The damper 86, which includes an air cylinder or a helical spring, for example, has a function to apply a force to urge the upper pressing bar 84 to move downwardly along the Z6-axis.

A blade 80 is slidably mounted on the slider 76 by a spacing adjuster 78. The blade 80 has a lower end portion tapered toward its lower distal end and is disposed adjacent to the upper pressing bar 84 along the Y6-axis.

The breaking apparatus 60 includes an unillustrated spacing adjuster moving mechanism for moving the spacing adjuster 78 along the Y6-axis. The spacing adjuster moving mechanism is a ball-screw-type moving mechanism having a ball screw, for example. The spacing adjuster moving mechanism moves the spacing adjuster 78 along the slider 76. When the spacing adjuster 78 is slid with respect to the slider 76, the spacing or distance between the blade 80 and the upper pressing bar 84 is varied, i.e., adjusted.

The breaking apparatus 60 includes an unillustrated upper unit moving mechanism for moving the upper unit 74 along the Z6-axis. The upper unit moving mechanism is a ball-screw-type moving mechanism having a ball screw, for example. The upper unit moving mechanism moves the upper unit 74 in directions along the Z6-axis.

The breaking apparatus 60 further includes one or more unillustrated delivery mechanisms for delivering the wafer 11 onto the support member 64. The delivery mechanism or mechanisms place the wafer 11 onto the upper surface 64a of the support member 64 such that the first surface 11a of the wafer 11 is exposed upwardly and the first tape 19 affixed to the second surface 11b thereof faces the upper surface 64a. Alternatively, the operator may manually deliver the wafer 11 onto the holding table 62. In a case where the operator manually delivers the wafer 11, the one or more delivery mechanisms for delivering the wafer 11 may be dispensed with.

The breaking apparatus 60 described above develops cracks initiated from the modified layers 27 in the wafer 11. For developing cracks in the wafer 11 in the gap forming step S6, the wafer 11 is initially held on the holding table 62. Specifically, the wafer 11 is positioned radially inwardly of the four clamps 66 on the support member 64 by the delivery mechanism or mechanisms such that the first surface 11a of the wafer 11 is exposed upwardly and the first tape 19 affixed to the second surface 11b thereof faces the upper surface 64a.

Thereafter, the movable clamps 66 are moved radially inwardly toward the center of the upper surface 64a until the wafer 11 is pushed against the fixed clamps 66. The wafer 11 is now secured in position to the holding table 62 by the four clamps 66 and held on the holding table 62. Then, the rotary actuator coupled to the support member 64 is energized to turn the support member 64 about its vertical axis until the first group of projected dicing lines 13a is oriented parallel to the X6-axis.

Then, the Y6-axis moving mechanism moves the holding table 62 in a direction along the Y6-axis. The position of the holding table 62 is adjusted by the Y6-axis moving mechanism to position a portion of the wafer 11 that is spaced a predetermined distance from one of the modified layers 27 between one of the lower pressing bars 72 and the upper pressing bar 84. Then, the lower unit 68 is elevated along the Z6-axis, and the upper unit 74 is lowered along the Z6-axis.

At this time, the damper 86 is actuated to cause the upper pressing bar 84 to press the wafer 11 under a certain force downwardly along the Z6-axis. The wafer 11 is now gripped under the force by the lower pressing bar 72 and the upper pressing bar 84.

Then, the upper unit moving mechanism is actuated to lower the blade 80 along the Z6-axis through the spacing adjuster 78 until the lower distal end of the blade 80 presses a portion of the wafer 11.

Since the wafer 11 is secured in position by the lower pressing bar 72 and the upper pressing bar 84 and is pressed by the blade 80, cracks 29 initiated from the modified layer 27 are developed in the wafer 11 and extend thicknesswise in the wafer 11. When the cracks 29 extend to the first surface 11a and the second surface 11b of the wafer 11, gaps 31 are formed in the wafer 11 along the respective projected dicing lines 13. The wafer 11 is now divided into individual device chips 33.

The distance along the Y6-axis between the blade 80 and the upper pressing bar 84 is preadjusted to a distance at which cracks 29 can efficiently be developed in the wafer 11 by the blade 80 pressing the wafer 11. The Y6-axis moving mechanism moves the holding table 62, and the blade 80 presses the wafer 11 along all the modified layers 27 therein, dividing the wafer 11 into a plurality of device chips 33. At this time, the modified layers 27 are left on the side faces of the device chips 33.

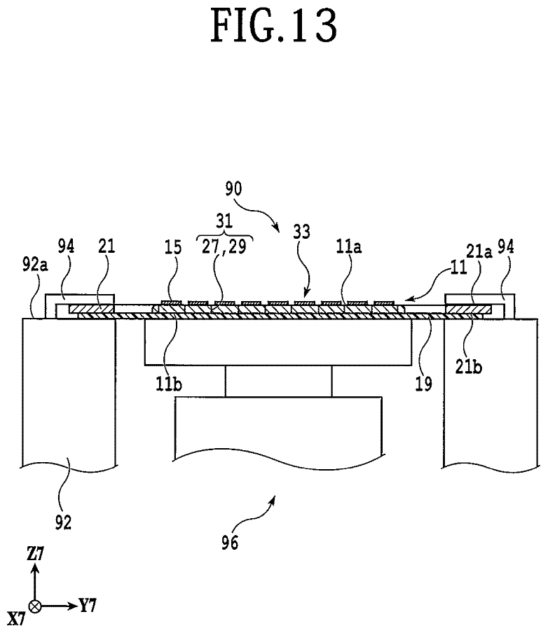

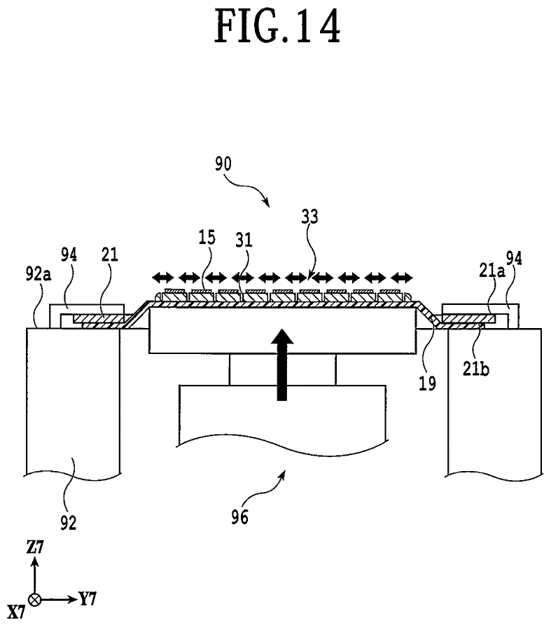

In the gap forming step S6, then, the first tape 19 is expanded to widen the gaps 31 between the device chips 33. The first tape 19 is expanded by an expanding apparatus 90 (see FIGS. 13 and 14). FIGS. 13 and 14 illustrate in side elevation, partly in cross section, the expanding apparatus 90, the wafer 11, and the frame 21 in the gap forming step S6. FIG. 13 illustrates the expanding apparatus 90, the wafer 11, and the frame 21 before the first tape 19 is expanded, and FIG. 14 illustrates the expanding apparatus 90, the wafer 11, and the frame 21 after the first tape 19 has been expanded. In FIGS. 13 and 14, the modified layers 27 on the side faces of the device chips 33 are omitted from illustration for clarification. In practice, the side faces of the device chips 33 where the modified layers 27 are present face each other across the gaps 31.

As illustrated in FIGS. 13 and 14, the expanding apparatus 90 has a holding table 92. The holding table 92 is a hollow cylindrical member made of a metal material such as stainless steel, for example. The holding table 92 has an upper surface 92a as a first surface on which there are mounted a plurality of clamps 94 for gripping the frame 21 securely in position on the upper surface 92a.

The expanding apparatus 90 also has a pressing mechanism 96 as a Z7-axis moving mechanism. The pressing mechanism 96 is disposed radially within the hollow cylindrical holding table 92. The pressing mechanism 96 is, for example, a moving mechanism having an air cylinder. When the pressing mechanism 96 moves upwardly along a Z7-axis indicated an arrow Z7 in FIGS. 13 and 14 that extends vertically perpendicularly to the upper surface 92a, the pressing mechanism 96 presses the first tape 19 upwardly within the frame 21 supported on the holding table 92.

The expanding apparatus 90 further includes one or more unillustrated delivery mechanisms disposed above the holding table 92 for delivering the wafer 11 onto the holding table 92. The wafer 11 is placed on the upper surface 92a of the holding table 92 by the delivery mechanism or mechanisms such that the first surface 11a of the wafer 11 is exposed upwardly and the first tape 19 affixed to the second surface 21b of the frame 21 is held in contact with the upper surface 92a. Alternatively, the operator may manually deliver the wafer 11 onto the holding table 92. In a case where the operator manually delivers the wafer 11, the one or more delivery mechanisms for delivering the wafer 11 may be dispensed with.

During a process of expanding the first tape 19, the wafer 11 is initially held on the holding table 92. Specifically, as illustrated in FIG. 13, the first tape 19 affixed to the second surface 21b of the frame 21 is placed on the upper surface 92a in facing relation thereto. Thereafter, the clamps 94 press the first surface 21a of the frame 21 downwardly toward the upper surface 92a. The wafer 11 is thus fixed securely in position on the holding table 92.

Then, as illustrated in FIG. 14, the pressing mechanism 96 is lifted along the Z7-axis, pressing the first tape 19 upwardly radially within the frame 21 supported on the holding table 92. When the first tape 19 is pressed upwardly, the first tape 19 is spread from its portion fixed by the clamps 94. The portion of the first tape 19 that is contacted by the pressing mechanism 96 is expanded radially outwardly in a horizontal X7Y7 plane that is defined by an X7-axis indicated by an arrow X7 in FIG. 14 and a Y7-axis indicated by an arrow Y7 in FIG. 14. The X7-axis and the Y7-axis extend horizontally perpendicularly to each other, and the Z7-axis extends vertically perpendicularly to the X7-axis and the Y7-axis. As a result, the gaps 31 between the adjacent ones of the device chips 33 are widened.

The wafer 11 may be divided only by the expanding apparatus 90, rather than the breaking apparatus 60, by developing the cracks 29 in the wafer 11. For example, when the expanding apparatus 90 expands the first tape 19, it applies forces to develop cracks from the modified layers 27 in the wafer 11, dividing the wafer 11 into individual device chips 33. If only the expanding apparatus 90 is used to divide the wafer 11, then the process carried out by the breaking apparatus 60 may be dispensed with.

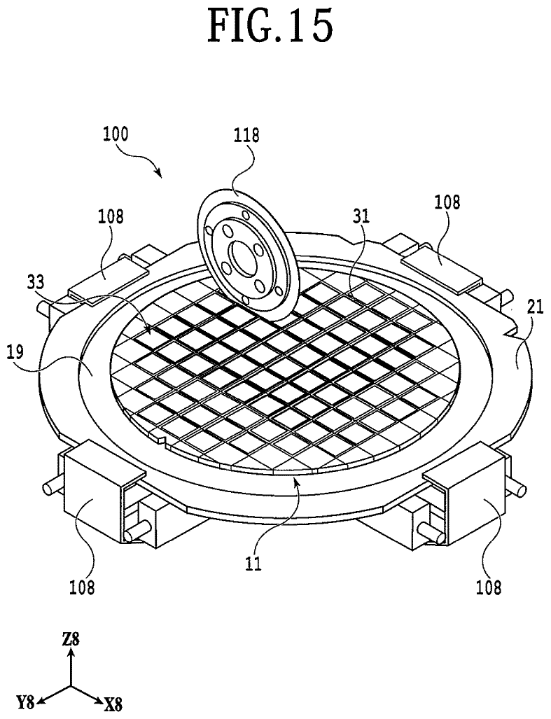

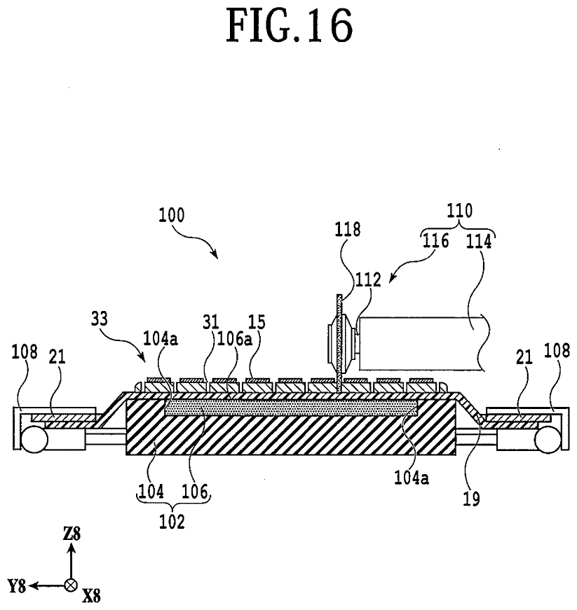

Then, the cutting step S7 is carried out to cut off the side faces of the device chips 33 where the modified layers 27 are left. The cutting step S7 is carried out by a cutting apparatus 100 (see FIGS. 15 and 16) that has an annular cutting blade to cut a workpiece. FIG. 15 illustrates in perspective the cutting apparatus 100, the wafer 11, and the frame 21 in the cutting step S7. FIG. 16 illustrates in side elevation, partly in cross section, the cutting apparatus 100, the wafer 11, and the frame 21 in the cutting step S7. As illustrated in FIG. 16, the cutting apparatus 100 has a holding table 102 and a cutting unit 110 having a cutting edge 118. In FIG. 15, the components of the cutting unit 110 other than the cutting edge 118 are omitted from illustration for clarification.

The holding table 102 is structurally similar to the holding tables of the mounter apparatus 2a and other apparatuses described above. Specifically, the holding table 102 includes a disk-shaped frame 104 made of a metal material such as stainless steel, for example. The frame 104 has a circular recess 104a that is defined in an upper surface thereof and that has an upper circular opening that is open upwardly. A disk-shaped holding plate 106 that is commensurate in shape with the recess 104a is fitted in the recess 104a. The holding plate 106 is a porous plate made of a ceramic or the like, for example. The holding table 102 holds the wafer 11 placed on an upper holding surface 106a of the holding plate 106.

The frame 104 has an unillustrated suction hole defined therein that has an end fluidly connected to the bottom of the recess 104a in the frame 104. The suction hole has another end fluidly connected to an unillustrated suction channel that is fluidly connected to an unillustrated suction source. The suction channel has an unillustrated valve that can selectively be opened and closed. When the suction source is actuated and the valve is opened, a negative pressure developed by the suction source is transmitted through the suction channel, the suction hole, and the holding plate 106 and acts on the holding surface 106a. The suction source is a vacuum pump that is a combination of an air supply source and an ejector, for example. However, the suction source may alternatively be a rotary pump.

The cutting apparatus 100 also has an unillustrated holding table moving mechanism for moving the holding table 102 in directions along an X8-axis indicated by an arrow X8 in FIGS. 15 and 16. The X8-axis moving mechanism is a ball-screw-type moving mechanism having a ball screw, for example. The holding table moving mechanism moves the holding table 102 along the X8-axis while the cutting unit 110 is cutting into the wafer 11 held on the holding table 102 along the projected dicing lines 13, thereby severing the wafer 11 or the device chips 33 along the projected dicing lines 13 or the gaps 31.

The holding table 102 is coupled to an unillustrated rotary actuator, such as an electric motor. When the rotary actuator is energized, it produces rotary drive power that rotates the holding table 102 about a vertical axis along a Z8-axis that extends through the center of the holding surface 106a perpendicularly to the holding surface 106a. The Z8-axis extends vertically and perpendicularly to the X8-axis and a Y8-axis indicated by the arrow Y8. The X8-axis and the Y8-axis extend horizontally perpendicularly to each other. A plurality of clamps 108 for fixing the wafer 11 on the holding surface 106a are disposed circumferentially around and coupled to the holding table 102.

The cutting unit 110 cuts the wafer 11, i.e., the device chips 33, held on the holding table 102. The cutting unit 110 has a horizontal spindle 112 having a longitudinal axis generally parallel to the Y8-axis. The cutting unit 110 also has a cutting blade 116 mounted on a distal end of the spindle 112. The spindle 112 has another end rotatably housed in a spindle housing 114. The spindle housing 114 houses therein an unillustrated electric motor as a rotary actuator coupled to the other end of the spindle 112. The cutting edge 118 of the cutting blade 116 is of an annular shape and made of abrasive grains of diamond, for example, dispersed in and bound by a bonding material such as metal, resin, or ceramic, for example.

The cutting apparatus 100 further includes an unillustrated cutting unit moving mechanism for moving the cutting unit 110 in directions along the Y8-axis and the Z8-axis. The cutting unit moving mechanism is a ball-screw-type moving mechanism having a ball screw, for example. The cutting unit 110 includes an unillustrated nozzle for supplying a processing liquid. The nozzle supplies the processing liquid to the tip end of the cutting blade 116, i.e., the cutting edge 118, and the wafer 11 while the wafer 11 is being cut by the cutting edge 118.

The cutting apparatus 100 further includes one or more unillustrated delivery mechanisms disposed above the holding table 102 for delivering the wafer 11, i.e., the device chips 33, onto the holding table 102. For example, the wafer 11 is placed on the holding table 102 by the delivery mechanism or mechanisms such that the first surface 11a of the wafer 11 is exposed upwardly and the first tape 19 affixed to the second surface 11b thereof faces the holding surface 106a. Alternatively, the operator may manually deliver the wafer 11 onto the holding table 102. In a case where the operator manually delivers the wafer 11, the one or more delivery mechanisms for delivering the wafer 11 may be dispensed with.

The cutting step S7 is carried out by the cutting apparatus 100. In the cutting step S7, the wafer 11 is initially held on the holding table 102. Specifically, the wafer 11 is placed on the holding table 102 by the delivery mechanism or mechanisms such that the first tape 19 affixed to the second surface 11b of the wafer 11 faces the holding surface 106a of the holding plate 106. Thereafter, the suction source is actuated and the valve is opened, transmitting the negative pressure from the suction source through the suction channel, the suction hole, and the holding table 102. The negative pressure acts on the holding surface 106a, thereby attracting the wafer 11 under suction to the holding surface 106a and holding the wafer 11 on the holding table 102.

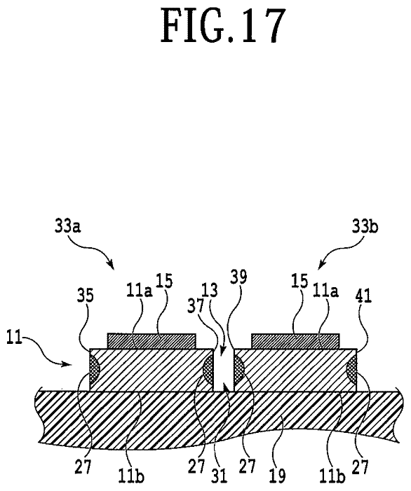

Then, the device chips 33 where the modified layers 27 are left on their side faces are cut by the cutting unit 110. FIG. 17 illustrates in enlarged fragmentary cross section the wafer 11, i.e., the device chips 33, in the cutting step S7. Specifically, as illustrated in FIG. 17, a first device chip 33a and a second device chip 33b that are positioned adjacent to each other across a projected dicing line 13, i.e., a gap 31, from each other are fixed to the first tape 19. Modified layers 27 are present in opposite side faces 35 and 37 of the first device chip 33a and opposite side faces 39 and 41 of the second device chip 33b.

The cutting apparatus 100 cuts off the side face 35 of the first device chip 33a, the side face 37 of the first device chip 33a, the side face 39 of the second device chip 33b, and the side face 41 of the second device chip 33b successively in the order named, thereby removing the modified layers 27 from the device chips 33a and 33b. A process of cutting off the side face 37 of the first device chip 33a and the side face 39 of the second device chip 33b will be described below.

The holding table 102 is turned about its vertical axis by the rotary actuator until the side face 37 of the first device chip 33a is oriented parallel to the X8-axis (see FIG. 16). Then, the positional relation between the cutting blade 116 of the cutting unit 110 and the wafer 11, i.e., the device chips 33, is adjusted. Specifically, the position along the X8-axis of the holding table 102 is adjusted by the holding table moving mechanism in order to put the cutting blade 116 in a position where it does not overlap the wafer 11 as viewed from above, i.e., in plan.

Moreover, the position of the cutting unit 110 along the Y8-axis is adjusted by the cutting unit moving mechanism in order to align the position of the cutting blade 116 along the Y8-axis with the side face 37 of the first device chip 33a.

Furthermore, the vertical position or height of the cutting unit 110 along the Z8-axis is adjusted by the cutting unit moving mechanism in order to position the lower end of the cutting blade 116 slightly below the second surface 11b of the wafer 11. At this time, the nozzle supplies the processing liquid to the tip end of the cutting blade 116 and the wafer 11. The electric motor coupled to the spindle 112 is energized to start rotating the spindle 112 and the cutting blade 116 about the longitudinal axis of the spindle 112.

Then, the holding table moving mechanism moves the holding table 102 along the X8-axis direction, i.e., a processing-feed direction. The cutting blade 116 and the holding table 102 are moved, i.e., processing-fed, relatively to each other along the X8-axis.

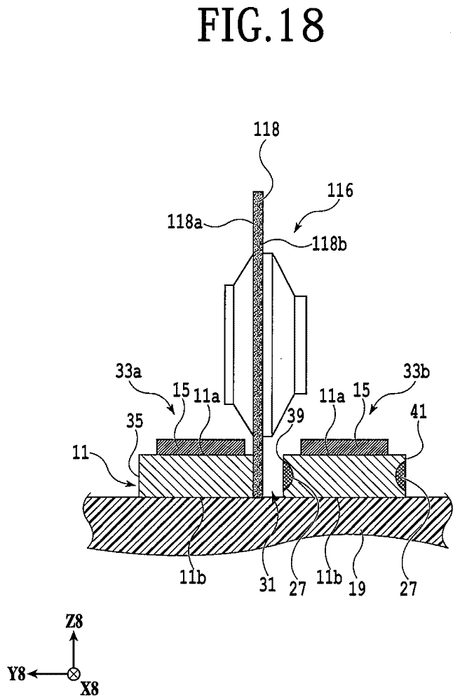

FIG. 18 illustrates in enlarged fragmentary cross section the cutting blade 116, the wafer 11, i.e., the device chips 33, and the first tape 19 in the cutting step S7. While the processing liquid is being supplied to the cutting blade 116 and the wafer 11, a first side surface 118a of the cutting edge 118 of the cutting blade 116 cuts into the modified layer 27 that is present in the side face 37 of the first device chip 33a from the wafer 11.

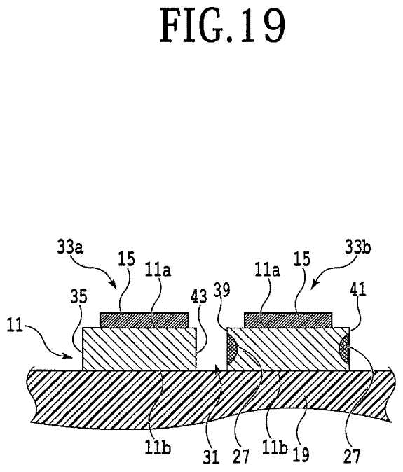

The cutting blade 116 as it cuts into the first device chip 33a along the X8-axis cuts off and removes the modified layer 27 from the first device chip 33a. FIG. 19 illustrates the wafer 11 in enlarged fragmentary cross section in the cutting step S7. As illustrated in FIG. 19, the wafer 11 now includes a side face 43 newly formed on the first device chip 33a by removing the modified layer 27 in the side face 37 thereof.

For example, providing the wafer 11 is made of sapphire and has a thickness of 1000 μm and the first tape 19 has a thickness of 250 μm, the cutting depth for the cutting blade 116, i.e., the cutting depth set in the cutting apparatus 100 as representing the distance from the first surface 11a of the wafer 11 to the lower tip end of the cutting blade 116, is set to 1080 μm, the feed speed, i.e., the speed at which to feed the holding table 102 along the X8-axis, is set to 5 mm/sec, the speed at which to rotate the spindle 112 is set to 30000 rpm, and the rate at which to supply the processing liquid is set to 4 L/min.

After the cutting blade 116 has cut off the modified layer 27 in the side face 37 of the first device chip 33a, the holding table moving mechanism stops moving the holding table 102 along the X8-axis. Thereafter, the height of the cutting unit 110 is adjusted by the cutting unit moving mechanism to space the lower tip end of the cutting blade 116 upwardly of the first surface 11a of the wafer 11 by a predetermined distance.

Then, the holding table moving mechanism moves the holding table 102 in a direction opposite the processing-feed direction along the X8-axis. Specifically, the holding table moving mechanism adjusts the position along the X8-axis of the holding table 102 until the cutting blade 116 is moved relatively to the wafer 11 to a position where it does not overlap the wafer 11 as viewed in plan.

Then, the position of the cutting unit 110 along the Y8-axis is adjusted by the cutting unit moving mechanism in order to align the position of the cutting blade 116 along the Y8-axis with the side face 39 of the second device chip 33b.

Further, the vertical position or height of the cutting unit 110 along the Z8-axis is adjusted by the cutting unit moving mechanism in order to position the lower end of the cutting blade 116 slightly below the second surface 11b of the wafer 11.

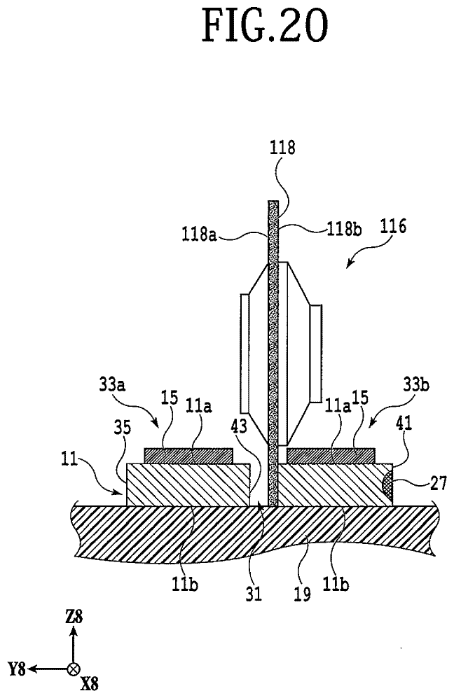

Thereafter, in the same manner as the above process of cutting off the modified layer 27 in the side face 37 of the first device chip 33a, a second side surface 118b of the cutting edge 118 of the cutting blade 116 cuts into the modified layer 27 that is present in the side face 39 of the second device chip 33b from the wafer 11. FIG. 20 illustrates in enlarged fragmentary side elevation, partly in cross section, the cutting blade 116, the wafer 11, and the first tape 19 in the cutting step S7. The cutting blade 116, as it cuts into the second device chip 33b along the X8-axis, cuts off and removes the modified layer 27 from the second device chip 33b.

After the cutting blade 116 has cut off the modified layer 27 in the side face 39 of the second device chip 33b, the holding table moving mechanism stops moving the holding table 102 along the X8-axis. Thereafter, the height of the cutting unit 110 is adjusted by the cutting unit moving mechanism to space the lower tip end of the cutting blade 116 upwardly of the first surface 11a of the wafer 11 by a predetermined distance.

Then, the holding table moving mechanism moves the holding table 102 in a direction opposite the processing-feed direction along the X8-axis. Specifically, the holding table moving mechanism adjusts the position along the X8-axis of the holding table 102 until the cutting blade 116 is moved relatively to the wafer 11 to a position where it does not overlap the wafer 11 as viewed in plan.

The above process is repeated to cut off the modified layer 27 in the side face 41 of the second device chip 33b. Thereafter, the modified layers 27 in the side faces of all the device chips 33 are similarly cut off, whereupon the sequence of the wafer processing method according to the present embodiment comes to an end.

According to the present embodiment, for dividing the wafer 11 into the device chips 33, the cutting blade 116 is not caused to cut into the wafer 11, but the laser beam 25 is applied to the wafer 11. Therefore, it is possible to reduce a material loss, i.e., a kerf loss, from the wafer 11 compared with a process of dividing the wafer 11 into the device chips 33 by causing the cutting blade 116 to cut into the wafer 11.

For example, if a wafer 11 made of sapphire is divided by a cutting blade, then the cutting blade needs to have a cutting edge that is approximately 0.3 mm thick. This thickness of the cutting edge is almost twice the thickness, e.g., in the range of 0.15 to 0.2 mm, of a cutting edge for cutting a wafer 11 made of silicon. The thicker the cutting edge is, the wider the kerfs cut in the wafer become, resulting in an increased kerf loss.

According to the present embodiment, moreover, the modified layers 27 left in the side faces of the device chips 33 are removed after the first tape 19 has been expanded to widen the gaps 31 between the device chips 33. Specifically, while part of the cutting edge 118 is being inserted into a widened gap 31 along a device chip 33, another part of the cutting edge 118 is caused to cut into a side face of the device chip 33. Consequently, the depth to which the cutting edge 118 cuts into the device chip 33 is smaller than if the gap 31 is not widened. As a result, the modified layers 27 left in the side faces of the device chips 33 are removed while the kerf loss is kept to a minimum, and the device chips 33 produced from the wafer 11 are of high quality.

For example, if the width of each modified layer 27 is in the range of 0.05 to 0.1 mm, then providing the gap between each pair of device chips 33 is approximately 0.1 mm wide, the modified layer 27 can sufficiently be removed by a cutting edge having an ordinary thickness in the range of 0.15 to 0.2 mm.

A second embodiment according to the present invention will be described below. A wafer processing method according to the second embodiment includes the second tape affixing step S1, the grinding step S2, the modified layer forming step S3, the first tape affixing step S4, the second tape peeling step S5, and the gap forming step S6 similar to those of the wafer processing method according to the first embodiment. According to the second embodiment, the wafer processing method includes a cutting step S7 that is carried out in a manner different from that of the cutting step S7 of the wafer processing method according to the first embodiment.

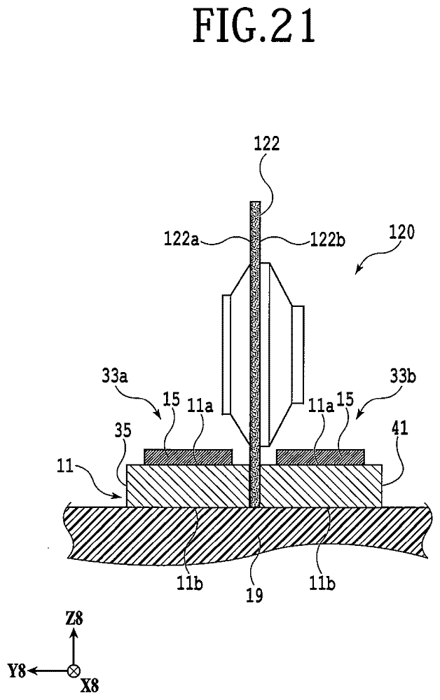

FIG. 21 illustrates in enlarged fragmentary side elevation, partly in cross section, a cutting blade 120, a wafer 11, and a first tape 19 in the cutting step S7 of the wafer processing method according to the second embodiment. In the cutting step S7 according to the first embodiment, after the side face, i.e., first side face, 37 of the first device chip 33a has been cut by the cutting blade 116, the side face, i.e., second side face, 39 of the second device chip 33b is cut by the cutting blade 116. In the cutting step S7 according to the second embodiment, the side face, i.e., first side face, 37 of the first device chip 33a and the side face, i.e., second side face, 39 of the second device chip 33b are simultaneously cut by the cutting blade 120.

Specifically, the cutting blade 120 includes an annular cutting edge 122 that has a first side surface 122a and a second side surface 122b opposite the first side surface 122a. At the same time that the first side surface 122a of the cutting edge 122 cuts into the side face 37 of the first device chip 33a, the second side surface 122b of the cutting edge 122 cuts into the side face 39 of the second device chip 33b. The cutting blade 120 is arranged to simultaneously cut off the modified layer 27 in the side face 37 of the first device chip 33a and the modified layer 27 in the side face 39 of the second device chip 33b.

According to the second embodiment, the modified layers 27 in the two device chips 33a and 33b that are disposed adjacent to each other can simultaneously be cut off and removed. Therefore, the cutting step S7 according to the second embodiment can be carried out more swiftly and simply than the cutting step S7 according to the first embodiment. As a result, the length of time required to process the wafer 11 is shortened.

A third embodiment of the present invention will be described below. A wafer processing method according to the third embodiment includes the second tape affixing step S1, the grinding step S2, the modified layer forming step S3, the first tape affixing step S4, the second tape peeling step S5, and the gap forming step S6 similar to those of the wafer processing methods according to the first and second embodiments. According to the third embodiment, the wafer processing method includes a cutting step S7 that is carried out in a manner different from those of the cutting steps S7 of the wafer processing methods according to the first and second embodiments.

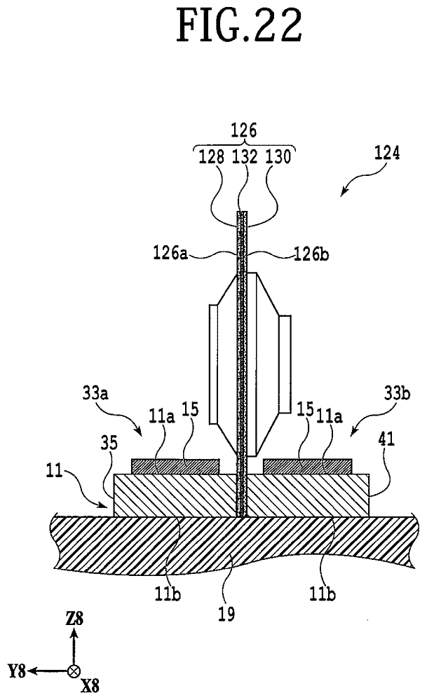

FIG. 22 illustrates in enlarged fragmentary side elevation, partly in cross section, a cutting blade 124, a wafer 11, and a first tape 19 in the cutting step S7 of the wafer processing method according to the third embodiment. The cutting blade 124 used in the cutting step S7 according to the third embodiment includes a layered cutting edge assembly 126 having a first cutting edge 128, a second cutting edge 130, and a third cutting edge 132 disposed between the first cutting edge 128 and the second cutting edge 130. The first cutting edge 128 has a first side surface 126a and the second cutting edge 130 has a second side surface 126b opposite the first side surface 126a. The third cutting edge 132 is more susceptible to wear than the first cutting edge 128 and is also more susceptible to wear than the second cutting edge 130.

The susceptibility of a cutting edge to wear can be adjusted by varying the density of abrasive grains contained in the cutting edge, the average particle size of the abrasive grains, and the porosity of the cutting edge and changing the material of a binder that binds the abrasive grains. For example, if the density of the abrasive grains contained in the third cutting edge 132 is lower than the density of the abrasive grains contained in the first cutting edge 128 and the density of the abrasive grains contained in the second cutting edge 130, then the third cutting edge 132 is more susceptible to wear than the first cutting edge 128 and the second cutting edge 130.

In addition, if the average particle size of the abrasive grains contained in the third cutting edge 132 is smaller than the average particle size of the abrasive grains contained in the first cutting edge 128 and the average particle size of the abrasive grains contained in the second cutting edge 130, then the third cutting edge 132 is more susceptible to wear than the first cutting edge 128 and the second cutting edge 130. Further, if the porosity of the third cutting edge 132 is higher than the porosity of the first cutting edge 128 and the porosity of the second cutting edge 130, then the third cutting edge 132 is more susceptible to wear than the first cutting edge 128 and the second cutting edge 130.

According to the third embodiment, after the side face, i.e., first side face, 37 of the first device chip 33a has been cut by the cutting blade 124, the side face, i.e., second side face, 39 of the second device chip 33b is cut by the cutting blade 124, as in the first embodiment. Specifically, the first side surface 126a of the first cutting edge 128 cuts into the side face 37 of the first device chip 33a, and thereafter the second side surface 126b of the second cutting edge 130 cuts into the side face 39 of the second device chip 33b.

Alternatively, according to the third embodiment, the side face 37 of the first device chip 33a and the side face 39 of the second device chip 33b are simultaneously cut by the cutting blade 124, as in the second embodiment. Specifically, at the same time that the first side surface 126a of the first cutting edge 128 cuts into the side face 37 of the first device chip 33a, the second side surface 126b of the second cutting edge 130 cuts into the side face 39 of the second device chip 33b.

Of the layered cutting edge assembly 126 according to the third embodiment, the third cutting edge 132 that does not cut into the first device chip 33a and the second device chip 33b is more susceptible to wear than the first cutting edge 128 that cuts into the first device chip 33a and the second cutting edge 130 that cuts into the second device chip 33b. The controlled susceptibility to wear of the layered cutting edge assembly 126 is effective to prevent the cutting blade 124 from suffering localized wear and to enable the cutting blade 124 to cut the wafer 11 appropriately.

According to the embodiments of the present invention, as described above, the laser beam 25 is applied to the wafer 11 to form the modified layers 27 in the wafer 11, and the cracks initiated from the modified layers 27 are developed in the wafer 11, thereby dividing the wafer 11 into the device chips 33. The kerf loss from the wafer 11 thus processed is reduced compared with the process of cutting the wafer 11 with the cutting blade to form dividing grooves in the wafer 11 and dividing the wafer 11 along the dividing grooves.

Moreover, after the wafer 11 has been divided into the device chips 33, the first tape 19 affixed to the wafer 11 is expanded to form the gaps 31 between the device chips 33. Thereafter, the cutting blade 116 is inserted into the gaps 31 and cuts off the side faces of the device chips 33. In this manner, the modified layers 27 exposed on the side faces of the device chips 33 are removed. As no material derived from the wafer 11 is present in the gaps 31, no material is lost by inserting the cutting blade 116 into the gaps 31. Even though the cutting blade 116 is used, since the cutting blade 116 cuts the device chips 33 by cutting into the side faces of the device chips 33 to a minimum depth required to remove the modified layers 27, the material loss is reduced.

The structural and methodical details according to the above embodiments and modifications thereof may be changed or modified without departing from the scope of the present invention.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A method of processing a wafer to fabricate a plurality of device chips from the wafer by dividing the wafer along projected dicing lines established on a face side of the wafer, comprising:
applying a laser beam having a wavelength transmittable through the wafer to the wafer along the projected dicing lines while focusing the laser beam within the wafer, thereby forming modified layers in the wafer along the projected dicing lines;
after the modified layers have been formed in the wafer, affixing a first tape to a reverse side, opposite the face side, of the wafer;
after the first tape has been affixed to the reverse side of the wafer, developing cracks initiated from the modified layers in the wafer to divide the wafer into a plurality of device chips, and expanding the first tape to form gaps between the device chips; and
after the gaps have been formed between the device chips, inserting a cutting blade into the gaps and causing the cutting blade to cut into side faces of the device chips, thereby cutting off the side faces of the device chips.

2. The method according to claim 1, wherein the gaps are formed by pressing the wafer to develop the cracks therein before the first tape is expanded.

3. The method according to claim 1, wherein
the device chips include a first device chip having a first side face and a second device chip that is disposed adjacent to the first device chip and that has a second side face that faces the first side face of the first device chip, and the cutting blade has an annular first surface and an annular second surface opposite the annular first surface,
the gaps are formed between the first side face of the first device chip and the second side face of the second device chip, and
the side faces of the device chips are cut by causing the annular first surface of the cutting blade to cut into the first side face of the first device chip and causing the annular second surface of the cutting blade to cut into the second side face of the second device chip, thereby simultaneously cutting off the first side face of the first device chip and the second side face of the second device chip.

4. The method according to claim 3, wherein
the cutting blade includes a layered cutting edge assembly having a first cutting edge having the annular first surface, a second cutting edge having the annular second surface, and a third cutting edge disposed between the first cutting edge and the second cutting edge,
the third cutting edge is more susceptible to wear than the first cutting edge,
the third cutting edge is more susceptible to wear than the second cutting edge, and
the side faces of the device chips are cut by causing the first cutting edge to cut off the first side face of the first device chip and causing the second cutting edge to cut off the second side face of the second device chip.

5. The method according to claim 1, further comprising:
before forming the modified layers, affixing a second tape to the face side of the wafer; and
after forming the modified layers but before cutting off the side faces of the device chips, peeling off the second tape from the face side of the wafer, wherein
the modified layers are formed by applying the laser beam to the wafer from the reverse side thereof, and
the side faces of the device chips are cut off by inserting the cutting blade into the gaps from the face side of the wafer.

6. The method according to claim 2, further comprising:
before forming the modified layers, affixing a second tape to the face side of the wafer; and
after forming the modified layers but before cutting off the side faces of the device chips, peeling off the second tape from the face side of the wafer, wherein
the modified layers are formed by applying the laser beam to the wafer from the reverse side thereof, and
the side faces of the device chips are cut off by inserting the cutting blade into the gaps from the face side of the wafer.

7. The method according to claim 3, further comprising:
before forming the modified layers, affixing a second tape to the face side of the wafer; and
after forming the modified layers but before cutting off the side faces of the device chips, peeling off the second tape from the face side of the wafer, wherein
the modified layers are formed by applying the laser beam to the wafer from the reverse side thereof, and
the side faces of the device chips are cut off by inserting the cutting blade into the gaps from the face side of the wafer.

8. The method according to claim 4, further comprising:
before forming the modified layers, affixing a second tape to the face side of the wafer; and
after forming the modified layers and before cutting off the side faces of the device chips, peeling off the second tape from the face side of the wafer, wherein
the modified layers are formed by applying the laser beam to the wafer from the reverse side thereof, and
the side faces of the device chips are cut off by inserting the cutting blade into the gaps from the face side of the wafer.
